(19) United States
(12) Patent Application Publication
(10) Pub. No.: US 2025/0285831 A1
(43) Pub. Date: Sep. 11, 2025

(54) MULTI-BEAM PARTICLE MICROSCOPE COMPRISING AN ABERRATION CORRECTION UNIT HAVING GEOMETRY-BASED CORRECTION ELECTRODES, AND METHOD FOR ADJUSTING THE ABERRATION CORRECTION, AND COMPUTER PROGRAM PRODUCT

(71) Applicant: Carl Zeiss MultiSEM GmbH, Oberkochen (DE)

(72) Inventors: Christian VEIT, Leinfelden-Echterdingen (DE); Dirk ZEIDLER, Oberkochen (DE); Benedikt TRATZMILLER, Stuttgart (DE); Ingo MUELLER, Aalen (DE)

(21) Appl. No.: 19/215,583

(22) Filed: May 22, 2025

Related U.S. Application Data
(63) Continuation of application No. PCT/EP2023/025491, filed on Nov. 21, 2023.

(30) Foreign Application Priority Data
Dec. 1, 2022 (DE) 10 2022 131 862.1

(51) Int. Cl. H01J 37/153; H01J 37/12; H01J 37/14; H01J 37/28

(52) U.S. Cl. CPC H01J 37/153; H01J 37/12; H01J 37/14; H01J 37/28; H01J 2237/1534

(57) ABSTRACT

A multi-beam particle microscope having an improved aberration correction unit comprising a sequence of electrode arrays comprising a first pair of electrode arrays. The first pair has first and second electrode arrays. The first electrode and second electrode arrays each has a multiplicity of geometry-based correction electrodes each having n-fold rotational symmetry about the optical axis for multipole field generation. Each of the geometry-based correction electrodes is controllable individually via exactly one feed line. The geometry-based correction electrodes in the first electrode array are rotated relative to associated geometry-based correction electrodes in the second electrode array in relation to the optical axis. The controller is designed to control the multiplicity of geometry-based correction electrodes of the first electrode array and of the second electrode array of the aberration correction unit individually for an aberration correction.

### CROSS-REFERENCE TO RELATED APPLICATIONS

The present application is a continuation of, and claims benefit under 35 USC 120 to, international application No. PCT/EP2023/025491, filed Nov. 21, 2023, which claims benefit under 35 USC 119 of German Application No. 10 2022 131 862.1, filed Dec. 1, 2022. The entire disclosure of each of these applications is incorporated by reference herein.

### FIELD

The disclosure relates to multi-beam particle beam systems. The disclosure relates specifically to a multi-beam particle microscope comprising an aberration correction unit, and to a method for adjusting the aberration correction, and to an associated computer program product.

### BACKGROUND

With the continuous development of ever smaller and ever more complex microstructures such as semiconductor components, there is a desire to further develop and optimize planar production techniques and inspection systems for producing and inspecting small dimensions of the microstructures. By way of example, the development and production of the semiconductor components involve monitoring of the design of test wafers, and the planar production techniques involve process optimization for reliable production with high throughput. Moreover, there have been recent demands for an analysis of semiconductor wafers for reverse engineering and for a customized, individual configuration of semiconductor components. Therefore, there is a desire for an inspection approach which can be used with high throughput to examine the microstructures on wafers with high accuracy.

Typical silicon wafers used in the production of semiconductor components have diameters of up to 300 millimeters (mm). Each wafer is divided into 30 to 60 repeating regions (“dies”) with a size of up to 800 square millimeters (mm²). A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few μm to the critical dimensions (CD) of 5 nanometers (nm), with the structure sizes becoming even smaller in the near future; in future, structure sizes or critical dimensions (CD) are expected to be less than 3 nm, for example 2 nm, or even under 1 nm. In the case of the aforementioned small structure sizes, defects in the size of the critical dimensions are identified quickly in a very large area. For several applications, the specification regarding the accuracy of a measurement provided by inspection equipment is even higher, for example by a factor of two or one order of magnitude. By way of example, a width of a semiconductor feature are measured with an accuracy of below 1 nm, for example 0.3 nm or even less, and a relative position of semiconductor structures are determined with an overlay accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a multiplicity of individual electron beams, which are arranged in a field or grid. By way of example, 4 to 10,000 individual electron beams can be provided as primary radiation, with each individual electron beam being separated from an adjacent individual electron beam by a pitch of 1 to 200 micrometres. By way of example, an MSEM has approximately 100 separate individual electron beams (“beamlets”), which are arranged for example in a hexagonal grid, with the individual electron beams being separated by a pitch of approximately 10 micrometers (μm). The multiplicity of charged individual particle beams (primary beams) are focused by a common objective lens onto a surface of a sample to be examined. By way of example, the sample can be a semiconductor wafer which is secured to a wafer holder mounted on a movable stage. During the illumination of the wafer surface with the charged primary individual particle beams, interaction products, for example secondary electrons or backscattered electrons, emanate from the surface of the wafer. Their start points correspond to those locations on the sample onto which the multiplicity of primary individual particle beams are focused in each case. The amount and the energy of the interaction products depend on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises a plurality of detection regions, each of which comprises a plurality of detection pixels, and the detector captures an intensity distribution for each of the secondary individual particle beams. An image field of, for example, 100 μm×100 μm is obtained in the process.

Certain known multi-beam electron microscopes comprise a sequence of electrostatic and magnetic elements. At least some of the electrostatic and magnetic elements are adjustable in order to adapt the focus position and the stigmation of the multiplicity of charged individual particle beams. Such multi-beam systems with charged particles moreover comprise at least one cross-over plane of the primary or the secondary charged individual particle beams. Moreover, such systems comprise detection systems in order to facilitate the adjustment. Such multi-beam particle microscopes comprise at least one beam deflector (“deflection scanner”) for collective scanning of a region of the sample surface via the multiplicity of primary individual particle beams in order to obtain an image field of the sample surface.

When carrying out inspection tasks using multi-beam particle microscopes, aberrations can occur, and it is desirable to avoid or reduce these. For this purpose, correctors which enable either global or individual beam corrections are used. Individual beam corrections can be desirable precisely when a multi-beam particle microscope has a large number of individual particle beams and thus a relatively large multi-field of view. In this regard, a field astigmatism typically occurs in the case of multi-beam particle microscopes, and this cannot be corrected by a global stigmator. Individual-beam correctors are used instead, typically having arrays of multipole electrodes, for example octupole electrodes. The electrodes are thus segmented and hence multipole electrodes. In this case, each electrode of the multipole electrodes is individually controllable. In this respect, reference is made by way of example to DE 10 2014 008 083 A1.

In this case, a multipole electrode can be used not only for correcting astigmatism, but also for correcting other aberrations. An octupole electrode can for example also deflect an individual particle beam or displace the focus position of the individual particle beam. In addition—somewhat less intuitively—geometric aberrations having three-fold symmetry can also be corrected via the octupole electrode.

The multipole electrodes described thus can provide very universal usability for aberration corrections. Nevertheless, the multipole electrodes in the case of multi-beam particle microscopes employing ever more individual particle beams are reaching their limits, and there can be a desire for improvement.

The multipole electrodes are implemented as large arrays, and their production is complex and comparatively expensive. Their complexity can make them susceptible, in general. Quality and service life can be difficult to ensure. For example, for each multipole electrode, a plurality of feed lines are used for the application of voltage to the electrodes. An octupole electrode having eight individually adjustable electrodes involves eight feed lines, for example. In the case of an octupole electrode array for more than 100 individual particle beams of a multi-beam particle microscope, this already adds up to more than 800 individual lines. Realistically it is no longer possible for such a high number of feed lines to be provided by way of vacuum bushings. Instead, the voltages for the feed lines are generated by an apparatus which is already arranged within the vacuum of the multi-beam particle microscope, for example by an application-specific integrated circuit (ASIC). An arrangement within the vacuum chamber is undesirable, however, owing to potential electron bombardment and owing to the x-ray radiation that unavoidably occurs in the chamber.

Moreover, when there is overall a large number of individually controllable electrodes in an array or in a multi-aperture plate, the feed line arrangement itself can be problematic. It can be desirable for very many lines to run between the individual octupole electrodes or in the interspaces between the apertures in a multi-aperture plate. In general, therefore, limits can be imposed on the size or the number of multipole electrodes in a multi-aperture plate. The system might not have good scalability. Even having recourse to laying lines in a plurality of planes might be appropriate as a solution only to a limited extent, since this approach likewise involves a comparatively high outlay.

EP 4 020 565 A1, making reference to EP 2 702 595 A1 and EP 2 715 768 A2, discloses a multi-beam particle beam system with aberration correction in order to correct for example an image field curvature, a focus position and an astigmatism. Multipole electrodes are used for the correction.

EP 2 339 608 A1 discloses, for the purpose of correcting aberrations, a plurality of plate sequences each having an opening with a specific geometry, whereby respective multipole fields are generated. Specifically, EP 2 339 608 A1 describes by way of example a hexapole corrector for correcting a spherical aberration. This aberration is rotationally symmetrical. In connection with multi-beam particle beam systems, EP 2 339 608 A1 discloses a system having a plurality of tips (“emitter tips”) for generating a multiplicity of particle beams. The generated multiplicity of particle beams respectively pass through sequences of a plurality of multi-aperture plates each having a plurality of openings with a specific geometry. In that case, a (global) voltage is applied to each multi-aperture plate. An identical aberration correction for all the particle beams can be realized as a result. Field profiles or a field-dependent individual aberration correction are not addressed in EP 2 339 608 A1, nor are they possible with the technology in EP 2 339 608 A1.

### SUMMARY

The disclosure seeks to overcome limitations of certain known systems. The disclosure seeks to provide a multi-beam particle microscope with aberration correction which enables an individual beam correction to be effected for a larger number of individual particle beams and/or with less control outlay. It is intended for a field-dependent correction to be possible individually for each individual particle beam.

A basic concept provided within the disclosure involves replacing certain multipole correctors, with their segmented electrodes that are to be controlled in a complicated manner, by a different type of correction unit.

In general, the following relationship holds true for the electrostatic potential U within a multipole corrector (indicated in cylindrical coordinates):

$$U ∝ {U}_{0} + {U}_{1} cos ( φ + {φ}_{1} ) + {U}_{2} cos ( 2 φ + {φ}_{2} ) + {U}_{3} cos ( 3 φ + {φ}_{3} ) + … \qquad ( equation 1 )$$

In this case, φ is the angle coordinate within the multipole corrector. The amplitudes U₁ . . . Uₙ are dependent on the position along the optical axis (z-axis), and they additionally have a radial dependence. The angles φᵢ describe a rotation or the alignment of a multipole.

The electrostatic potential U within a multipole corrector can thus be represented in general by a series expansion with respect to multipoles. U₁ cos (φ+φ₁) describes a dipole, U₂ cos (2φ+φ₂) describes a quadrupole, U₃ cos (3φ+φ₃) describes a hexapole, etc., and U₀ is a radially symmetrical offset potential.

Instead of—as in certain known systems—generating the entire potential used for aberration correction via a single multipole corrector, the electrodes which are controlled in a complicated manner, according to the disclosure individual terms of the series expansion above are realized separately by specific electrode pairs. All terms of the correction potential can be represented by a sequence of these specific electrode pairs. In this case, the specific electrodes of the electrode pairs are each individually controllable, but each use only exactly one feed line, which reduces the number of feed lines overall in the aberration correction unit and reduces the control outlay. Something of interest here for the respective multipole generation in the sequence composed of specific electrodes or electrode pairs is the shape or the shape of the cross-sections of these electrodes. They are therefore referred to as geometry-based electrodes in the context of this patent application. A geometry-based electrode can for example have an elliptic cross-section, i.e. two-fold symmetry, and thus generate a quadrupole field. It can have in cross-section a substantially rounded equilateral triangle shape, i.e. three-fold symmetry, which generates a hexapole field, etc.

In accordance with a first aspect, the disclosure relates to a multi-beam particle microscope, having the following features: a multi-beam generator configured to generate a first field of a multiplicity of charged first individual particle beams; a first particle optical unit with a first particle optical beam path, configured to image the generated first individual particle beams onto a sample surface in the object plane such that the first individual particle beams are incident on the sample surface at incidence locations, which form a second field; a detection system with a multiplicity of detection regions that form a third field; a second particle optical unit with a second particle optical beam path, configured to image second individual particle beams, which emanate from the incidence locations in the second field, onto the third field of the detection regions of the detection system; a magnetic and/or electrostatic objective lens, through which both the first and the second individual particle beams pass; a beam switch, which is arranged in the first particle optical beam path between the multi-beam generator and the objective lens and which is arranged in the second particle optical beam path between the objective lens and the detection system; an aberration correction unit for individually correcting one or more aberrations in the first particle optical beam path; and a controller, wherein the aberration correction unit has a sequence of electrode arrays comprising at least one first pair of electrode arrays, wherein the first pair has a first electrode array and a second electrode array, wherein the first electrode array and the second electrode array each have a multiplicity of geometry-based correction electrodes each having n-fold rotational symmetry about the optical axis for multipole field generation, which are each controllable individually via exactly one feed line, wherein the geometry-based correction electrodes in the first electrode array are rotated relative to associated geometry-based correction electrodes in the second electrode array in relation to the optical axis; and wherein the controller is designed to control the multiplicity of geometry-based correction electrodes of the first electrode array and of the second electrode array of the aberration correction unit individually for an aberration correction.

The first charged individual particle beams can be, for example, electrons, positrons, muons or ions or other charged particles. It can be desirable for the number of particle beams to be 3n(n−1)+1, where n is any natural number; an arrangement of the particle beams in the array is then optionally hexagonal overall. The second individual particle beams can be backscattered electrons or secondary electrons. In this case, for analysis purposes it is possible for the low-energy secondary electrons to be used for image generation. However, it is also possible for mirror ions/mirror electrons to be used as second individual particle beams, that is to say first individual particle beams undergoing reversal directly upstream of or at the object.

The aberration correction unit can serve for individually correcting one or more aberrations in the first particle optical beam path. In this case, therefore, aberrations are corrected individually for the first individual particle beams. This does not involve a global correction equally for all the first individual particle beams. Instead, each of the geometry-based correction electrodes is controlled individually via exactly one line. The aberration correction unit has a sequence of electrode arrays comprising at least one first pair of electrode arrays, wherein the first pair has a first electrode array and a second electrode array. In this case, the word sequence describes the fact that the electrode arrays are arranged in succession, in general, in the particle optical beam path. However, it is not necessarily the case here that the first electrode array and the second electrode array are arranged directly successively. It is also possible for a further element of the aberration correction unit or even a totally different element to be situated between the first electrode array and the second electrode array. Overall, the aberration correction unit can be embodied integrally or in multipartite fashion.

The fact that the first electrode array and the second electrode array are embodied as a pair or referred to as a pair is intended to reflect the fact that a multipole of any desired orientation can be generated via the first electrode array and the second electrode array. The term “pair” is thus substantially about the interplay between the first electrode array and the second electrode array.

The first electrode array and the second electrode array each have a multiplicity of geometry-based correction electrodes each having n-fold rotational symmetry about the optical axis for multipole field generation, wherein each geometry-based correction electrode is controllable in each case individually via exactly one feed line. The electrical multipoles can be a dipole, a quadrupole, a hexapole, an octupole, a decapole, a dodecapole, etc., in accordance with the series expansion indicated in equation (1). The geometry-based correction electrodes of the first electrode array and of the second electrode array have the same n-fold rotational symmetry about the optical axis. In this case, the respective optical axis is considered for each first individual particle beam. The order n of rotational symmetry is defined here as usual in mathematics. A two-dimensional geometric figure is rotationally symmetrical if the figure has a central point and the figure is mapped onto itself when it is rotated about this point. A circle or an annulus is rotationally symmetrical in the narrower sense. It is mapped onto itself by a rotation by any arbitrary angle. However, a figure is also called rotationally symmetrical if it can be mapped onto itself by being rotated about the central point by a fixed angle φ where 0°<φ<360°. The angle of rotation can only be produced by dividing the full angle by a natural number n>1, i.e.

$$φ = \frac{360 °}{n} .$$

This number n is a characteristic number of rotational symmetry and is also referred to as the order of symmetry. Accordingly, this symmetry is also called n-fold rotational symmetry or n-fold radial symmetry. In the trivial case n=1, there is no rotational symmetry/radial symmetry; the case n=1 is concomitantly encompassed in this application and denotes the identical mapping in the event of a rotation by 360°. A geometry-based correction electrode having a round cross-section, but arranged in a manner displaced relative to the optical axis, has no rotational symmetry, or has 1-fold symmetry in the context of the definition above. A geometry-based correction electrode having an elliptic cross-section, arranged centrally in relation to the optical axis, has 2-fold symmetry. An equilateral triangle or a corresponding shape having rounded corners, arranged centrally on the optical axis, has 3-fold symmetry, etc. Generally, regular n-polygons have corresponding n-fold rotational symmetry that can be used for multipole field generation in the sense of the series expansion above.

According to the disclosure, the geometry-based correction electrodes in the first electrode array are rotated relative to associated geometry-based correction electrodes in the second electrode array in relation to the optical axis. Two geometry-based correction electrodes arranged sequentially are associated if the same first individual particle beam passes through them. Rotating the geometry-based correction electrodes relative to one another makes it possible to align the generated multipole in any desired direction. It is optionally the case that the alignment of all geometry-based correction electrodes in the same electrode array is identical. This can help facilitate manufacturing the electrode array. However, it is also possible for the shape of the geometry-based correction electrodes in an electrode array to be identical, but for the alignment to vary. This variation of alignment should then correspondingly be reflected in the second electrode array as well, in order that the angle of rotation is then the same again for all pairs of geometry-based correction electrodes.

In accordance with one embodiment of the disclosure, an angle of rotation by which the geometry-based correction electrodes of the first pair are rotated with respect to one another is substantially 90°/n. Such an angle of rotation allows the formation of two fundamental multipoles, or that is to say substantially the formation of a cosine term (cos n φ) and a sine term (sin n φ) of the desired multipole of the series expansion in accordance with equation (1). If the angle between the generated multipoles is 90°/n, then excitations of the geometry-based correction electrodes of each pair of correction electrodes are independent of one another. This can provide certain desirable features when adjusting an aberration correction.

In accordance with an embodiment of the disclosure, the aberration correction unit has a second pair of electrode arrays, wherein the second pair has a third electrode array and a fourth electrode array, wherein the third electrode array and the fourth electrode array each have a multiplicity of geometry-based correction electrodes each having m-fold rotational symmetry about the optical axis for multipole field generation, which are each controllable individually via exactly one feed line, wherein the geometry-based correction electrodes in the third electrode array are rotated relative to associated geometry-based correction electrodes in the fourth electrode array in relation to the optical axis; and wherein the controller is designed to control the multiplicity of geometry-based correction electrodes of the third electrode array and of the fourth electrode array of the aberration correction unit individually for an aberration correction.

What holds true for the second pair of electrode arrays is substantially the same as what holds true for the first pair of electrode arrays. Normally, however, the second pair of electrode arrays generates a different multipole field of the multipole expansion compared with that generated by the first pair of electrode arrays. This is also expressed by the m-fold rotational symmetry of the geometry-based correction electrodes, wherein the following normally holds true here: n≠m given n, m∈ [symbol] .

In accordance with one embodiment of the disclosure, an angle of rotation by which the geometry-based correction electrodes of the second pair are rotated with respect to one another is substantially 90°/m. If it holds true that n≠m, then the angle of rotation describing the rotation of the first pair is thus also a different angle of rotation from the angle of rotation describing the rotation of the correction electrodes of the second pair with respect to one another.

In accordance with an embodiment of the disclosure, the aberration correction unit has a third pair of electrode arrays, wherein the third pair has a fifth electrode array and a sixth electrode array, wherein the fifth electrode array and the sixth electrode array each have a multiplicity of geometry-based correction electrodes each having k-fold rotational symmetry about the optical axis for multipole field generation, which are each controllable individually via exactly one feed line, wherein the geometry-based correction electrodes in the fifth electrode array are rotated relative to associated geometry-based correction electrodes in the sixth electrode array in relation to the optical axis; and wherein the controller is designed to control the multiplicity of geometry-based correction electrodes of the fifth electrode array and of the sixth electrode array of the aberration correction unit individually for an aberration correction.

What holds true for the third pair of electrode arrays, too, is substantially what has already been explained above for the first pair of electrode arrays and the second pair of electrode arrays. Via a total of three pairs of electrode arrays having geometry-based correction electrodes with different orders of symmetry, a total of three different multipoles of the series expansion described above can thus be realized. It should be emphasized again here that the ordinal number in relation to the electrode array need not indicate the position or the order of the electrode array in the particle optical beam path, but this may of course be the case.

In accordance with one embodiment of the disclosure, an angle of rotation by which the geometry-based correction electrodes of the third pair are rotated with respect to one another is substantially 90°/k. In this case, k∈ [symbol] and it can hold true that k≠n and k≠m.

In accordance with one embodiment of the disclosure, different pairs of electrode arrays have different orders of symmetry in the case of their respective geometry-based correction electrodes for generating different multipole fields. A first pair can generate a dipole field, for example, a second pair can generate a quadrupole field, a third pair can generate a hexapole field, etc.

In accordance with one embodiment of the disclosure, the geometry-based correction electrodes of a pair of electrode arrays are embodied so as to be round in cross-section, wherein the round correction electrodes in each of the electrode arrays forming the pair are displaced relative to the optical axis orthogonally with respect to the optical axis in different directions, for example by approximately 90°; wherein the controller is configured to control the cross-sectionally round correction electrodes individually for an aberration correction. For example, this control can substantially serve for correcting a static distortion of the second field of first individual particle beams upon incidence in the object plane.

As a result of the displacement of the correction electrodes embodied so as to be round in cross-section, there is no rotational symmetry; instead, the trivial case n=1 holds true for the order of symmetry. By virtue of the fact that the respective individual particle beam passes through the geometry-based correction electrode in a displaced manner, rather than centrally, a deflection takes place in each case. If the rotation of the cross-sectionally round correction electrodes is approximately 90° with respect to one another, then this corresponds to a displacement in the x-direction and y-direction. A distortion correction in the object plane can be corrected in a relatively simple manner in this case.

In accordance with an embodiment of the disclosure, the geometry-based correction electrodes of a pair of electrode arrays are embodied so as to be substantially elliptic in cross-section in order to generate a quadrupole field, wherein the substantially elliptic correction electrodes in each of the electrode arrays forming the pair are rotated relative to one another about the optical axis, for example rotated relative to one another substantially by 45°; wherein the controller is configured to control the elliptic correction electrodes substantially for individually correcting an astigmatism of the first individual particle beams.

In the case of a rotation by substantially 45° with respect to one another, the two quadrupoles generated are fundamental quadrupoles and they can be optimized independently of one another in terms of their excitation.

In accordance with an embodiment of the disclosure, the geometry-based correction electrodes of a pair of electrode arrays are embodied substantially as a rounded triangular shape in cross-section in order to form a hexapole field, wherein the substantially triangular correction electrodes in each of the electrode arrays forming the pair are rotated relative to one another about the optical axis, for example rotated relative to one another by substantially 30°; and wherein the controller is configured to individually control the substantially triangular correction electrodes substantially for correcting aberrations having 3-fold symmetry. These aberrations having 3-fold symmetry are thus higher-order aberrations. These can occur for example as part of unsystematic aberrations in a multi-beam particle microscope. Depending on the set-up of the optical system, a 3-fold astigmatism with field profile can also occur, which can be corrected by way of suitable control of the electrodes.

In accordance with an embodiment of the disclosure, the sequence of electrode arrays of the aberration correction unit has a further electrode array comprising a multiplicity of geometry-based correction electrodes which have a round cross-section and which are arranged in a centred fashion in relation to the respective optical axis, wherein the controller is designed to control the multiplicity of geometry-based correction electrodes of the further electrode array individually substantially for correcting a focus position of the first individual particle beams, for example for image field curvature correction and/or image field inclination correction.

The further electrode array thus differs from the previously described electrode arrays in multiple respects. The electrode array is not provided in pairwise fashion and its electrodes are strictly rotationally symmetrical, i.e. rotationally symmetrical in the narrower sense about the respective optical axis. In association with the present disclosure, the further electrode array makes it possible to realize the offset U₀ in accordance with the multipole expansion in accordance with equation (1).

In accordance with one embodiment of the disclosure, the electrode arrays are integrated into a multi-aperture plate. In this case, the electrodes extend substantially through the multi-aperture plate or are arranged within the openings. In accordance with one embodiment variant, provision is made here for one electrode array per multi-aperture plate. Alternative embodiment variants are also described further below.

In accordance with one embodiment of the disclosure, a standard multi-aperture plate having a multiplicity of passive round apertures is arranged between two mutually adjacent multi-aperture plates with, integrated therein, electrode arrays having individually controllable geometry-based correction electrodes. The standard multi-aperture plate therefore does not include an electrode array having individually controllable electrodes. Optionally, the standard multi-aperture plate is earthed, but it is also possible for a voltage to be applied to the standard multi-aperture plate, and then all of the round apertures are at the same potential. Providing a standard multi-aperture plate between two mutually adjacent multi-aperture plates with, integrated therein, electrode arrays having individually controllable geometry-based correction electrodes means that an alignment of the multipoles generated via the electrode arrays of a pair can be controlled or decoupled from one another. In general, two geometry-based correction electrodes per generated multipole are used in order to realize arbitrary alignments of this multipole. In line with the concept of the series expansion, a cosine term (cos n φ) is realized via one geometry-based electrode and a sine term (sin n φ) of the desired multipole is realized via the other geometry-based correction electrode. The two terms describe the fundamental multipoles. The angle between the two fundamental multipoles is dependent on the order of the multipole and is 90°/n. If the angle between the generated multipoles is exactly 90°/n, then optimum excitations of the geometry-based correction electrodes of a pair are independent of one another. Strictly speaking, however, it is the case that the orientation of a quadrupole generated by the application of a potential U₁ to the geometry-based correction electrode varies along the axial z-position. Charged particles of the individual particle beam which pass through the geometry-based correction electrode therefore experience an effective quadrupole field which is rotated (for example cos (2φ+φ) instead of cos (2φ)). The same correspondingly applies to a quadrupole generated by the application of a potential U₂ at the second geometry-based correction electrode of a pair of electrodes; this quadrupole can no longer be described by a pure sine term. For this reason, the angle between the two quadrupoles is no longer exactly 45°. This effect is in each case small, but nonetheless measurable. In accordance with one embodiment of the disclosure, the undesired deviations from the exact angle can be corrected by virtue of the fact that a standard multi-aperture plate having a multiplicity of passive round apertures is arranged between the mutually adjacent multi-aperture plates with, integrated therein, electrode arrays having individually controllable geometry-based correction electrodes. The standard multi-aperture plate serves as a counterelectrode. It can be the case that a respective standard multi-aperture plate having a multiplicity of passive round apertures is arranged between all mutually adjacent multi-aperture plates with, integrated therein, electrode arrays having individually controllable geometry-based correction electrodes.

In accordance with an embodiment of the disclosure, the aberration correction unit has a standard multi-aperture plate having a multiplicity of passive round apertures, which is arranged, in relation to the direction of the particle optical beam path, upstream of the first multi-aperture plate with individually controllable geometry-based correction electrodes; and/or the aberration correction unit has a standard multi-aperture plate having a multiplicity of passive round apertures, which is arranged, in relation to the direction of the particle optical beam path, downstream of the last multi-aperture plate with individually controllable geometry-based correction electrodes.

In the case of this embodiment variant, the introductory standard multi-aperture plate of the sequence of multi-aperture plates and also the finally arranged standard multi-aperture plate in relation to the sequence of multi-aperture plates ensure that the first generated multipole and respectively the last generated multipole are also oriented exactly or fundamental multipoles that are actually decoupled from one another can also be generated by two pairs of associated multi-aperture plates with electrode arrays integrated therein.

An alternative solution for producing the orthogonality of the generated multipoles pursues the path of altering the angle of rotation between the geometry-based correction electrodes of a pair of electrode arrays, as a result of which the multipoles thus produced do not mix. However, it is not possible to rule out such an arrangement generating additional multipoles of a different, for example higher, order that would not arise in this way in the case of an exact rotation by 90°/n of the correction electrodes.

A further solution approach is to use suitable linear combinations of excitations of the geometry-based correction electrodes so that the generated multipoles are prevented from mixing. By way of example, an amplitude matrix describing the relationship between the excitations of the correction electrodes and the amplitudes of the fundamental multipoles generated can be generated for this purpose. This matrix can be inverted so that the desired linear combinations of excitations of the correction electrodes can be ascertained.

In accordance with an embodiment of the disclosure, the aberration correction unit provides a carrier plate for a pair of electrode arrays, the geometry-based electrodes of the first electrode array being arranged on the top side of the carrier plate and the geometry-based electrodes of the second electrode array being arranged on the underside of the carrier plate. In this embodiment variant, it is therefore the case that the electrodes of the electrode array can actually be applied to the carrier plate, which of course has corresponding apertures. In this case, the geometry-based correction electrodes are insulated from the carrier plate itself. In this embodiment, the electrodes project from the carrier plate or protrude from the carrier plate. In this case, the geometry-based correction electrodes of each pair of geometry-based correction electrodes can be rotated relative to one another substantially by 90°/n in order to provide the fundamental multipoles for the aberration correction as exactly as possible.

In accordance with an embodiment of the disclosure, the aberration correction unit provides a carrier plate for a pair of electrode arrays, the geometry-based electrodes of the first electrode array being incorporated into the carrier plate on the top side and the geometry-based electrodes of the second electrode array being incorporated into the carrier plate on the underside. In this case, the geometry-based electrodes optionally do not project over the carrier plate, but rather are optionally integrated flush into the carrier plate. In this case, the geometry-based correction electrodes are insulated from the carrier plate itself.

The aberration correction unit can be produced via established manufacturing methods used e.g. in MEMS manufacture or in the production of integrated circuits. In this case, the aberration correction unit can be produced for example wholly or partly as a monolithic sandwich structure. In this case, it may be desirable to arrange insulator layers between the individual plates or electrode arrays of a monolithic sandwich structure. It is also possible for a plurality of functional layers of the aberration correction unit to be joined together to form monolithic plates and for these plates then to be stacked and aligned exactly with one another. Alternatively, it is possible for each functional layer to be embodied as an individual plate and for these plates then to be stacked and aligned exactly with one another. An accuracy in the submicron range may be used for such an exact alignment.

In accordance with an embodiment of the disclosure, the multi-beam particle microscope furthermore has a multipole amplitude input unit, via which a user can input amplitudes of multipoles to be generated, wherein the controller of the multi-beam particle microscope is designed to generate the control signals for controlling the geometry-based correction electrodes on the basis of the user input. If the multipoles are fundamental multipoles, then by varying the corresponding excitations a user can correct aberrations that occur during imaging in a very targeted manner.

In accordance with one embodiment of the disclosure, the controller of the multi-beam particle microscope is designed to carry out the ascertaining of control signals for controlling the geometry-based correction electrodes for multipole field generation using an inverted amplitude matrix, wherein the non-inverted amplitude matrix describes the relationship between the excitations of the correction electrodes and the amplitudes of the fundamental multipoles generated. Via the inverted amplitude matrix, it is possible to determine the suitable linear combination of excitations which leads to a desired amplitude distribution of the fundamental multipoles. For example, such a procedure enables suitable linear combinations of excitations to be found in order to generate a single (quite specific) multipole.

The above-described embodiment variants of the multi-beam particle microscope can be combined wholly or partly with one another, provided that no technical contradictions arise as a result.

In accordance with a second aspect of the disclosure, the latter relates to a method for generating fundamental multipoles for an aberration correction in a multi-beam particle microscope, the method having the following steps:
a0) providing a multi-beam particle microscope as described above in a plurality of embodiment variants;
a) for all geometry-based correction electrodes of a sequence:
   a1) exciting only one of the geometry-based correction electrodes;
   a2) determining all of the amplitudes of multipoles generated by the individual excitation;
b) establishing an amplitude matrix on the basis of the ascertained amplitudes, wherein the amplitude matrix describes the relationship between the excitations of the geometry-based correction electrodes and the amplitudes of the fundamental multipoles generated by these excitations;
c) inverting the amplitude matrix; and
d) exciting the geometry-based correction electrodes on the basis of the entries of the inverted amplitude matrix.

In general, this involves ascertaining separately for each of the geometry-based correction electrodes what further multipoles are generated by an excitation of the geometry-based correction electrode otherwise within the sequence of geometry-based correction electrodes. By way of example, it may be established that an excitation of the first geometry-based correction electrode principally brings about a dipole cos φ with amplitude A1, furthermore a dipole sin φ with the amplitude B1, a quadrupole cos 2 φ with the amplitude A2, a quadrupole sin 2 φ with the amplitude B2, etc. In this case, the exact unit with which these amplitudes are determined is not relevant.

In accordance with one embodiment of the disclosure, method step a2) comprises compensating for the effect of the multipole respectively generated, via a global multipole corrector, for example via a twelve-pole corrector, and ascertaining an amplitude respectively used for this purpose in the global multipole corrector. In this case, it is possible to provide a corresponding global multipole corrector only for purposes of adjustment of the multi-beam particle microscope; this corrector need not, but can, be permanently installed in the multi-beam particle microscope. However, the entries in the amplitude matrix can also be determined in some other way.

In accordance with an embodiment of the disclosure, the method furthermore has the following step:
e) optimizing the resolution of the multi-beam particle microscope comprising independently varying the amplitudes of each multipole and ascertaining the optimum amplitudes for the resolution.

It is also possible, of course, to correspondingly optimize an imaging property other than the resolution. The optimization of the resolution can be desirable, however, for multi-beam particle microscopes. The optimization of the resolution comprising the variations of the amplitudes of each multipole can be relatively simple for the case where the amplitude matrix of the corrector is diagonal or the inverted amplitude matrix has been determined. This is because an independent variation of the amplitudes of each multipole is then actually possible in the first place.

In accordance with an embodiment of the disclosure, the method is carried out for all the sequences of the geometry-based correction electrodes. The method is thus carried out for each individual particle beam. In this way, it is possible to individually correct imaging aberrations for each of the first individual particle beams in the object plane.

In accordance with one embodiment of the disclosure, by way of exciting the geometry-based correction electrodes, a field-dependent aberration correction is effected. For example, a previously known field dependence of aberrations can be corrected.

In accordance with a third aspect of the disclosure, the latter relates to a computer program product having a program code for carrying out the method as described above in a plurality of embodiment variants. In this case, the program code can be written in any desired programming language. The program code can be embodied in one part or in multipartite fashion. For example, it is desirable to provide a separate program code just for the control of the aberration correction unit. However, this can also be accomplished in a different way.

In accordance with a further aspect of the disclosure, the latter relates to a multi-beam particle beam system, having the following features: a multi-beam generator configured to generate a first field of a multiplicity of charged first individual particle beams; a particle optical unit with a first particle optical beam path, configured to image the generated individual particle beams onto a sample surface in the object plane such that the individual particle beams are incident on the sample surface at incidence locations, which form a second field; an aberration correction unit for individually correcting one or more aberrations in the particle optical beam path; and a controller, wherein the aberration correction unit has at least one electrode array, wherein the electrode array has a multiplicity of geometry-based correction electrodes each having n-fold rotational symmetry about the optical axis for multipole generation, which are each controllable individually for example via exactly one feed line, and wherein the controller is designed to control the multiplicity of geometry-based correction electrodes of the electrode array of the aberration correction unit individually for an aberration correction.

The multi-beam particle beam system in accordance with the fourth aspect of the disclosure describes the disclosure more broadly than the multi-beam particle microscope in accordance with the first aspect of the disclosure. The multi-beam particle beam system can be a multi-beam particle microscope, but this is not necessarily the case.

Regarding the terms used in connection with the fourth aspect of the disclosure, reference is explicitly made to the definition of the corresponding terms in connection with the first aspect of the disclosure. For example, all embodiments of the disclosure in accordance with the first aspect can also be combined with the multi-beam particle beam system in accordance with the fourth aspect of the disclosure. Only special features of the fourth aspect of the disclosure will be discussed below, in order to avoid unnecessary repetitions.

In accordance with the fourth aspect of the disclosure, the aberration correction unit has at least one electrode array. It is therefore also possible for the aberration correction unit to have only exactly one electrode array, wherein this electrode array again has a multiplicity of geometry-based correction electrodes each having n-fold rotational symmetry about the optical axis for multipole field generation, which are each controllable individually via a feed line; accordingly, the controller is designed to control the multiplicity of geometry-based correction electrodes of the electrode array of the aberration correction unit individually for an aberration correction.

By using only one electrode array, it is still possible to carry out an aberration correction, but no longer with the universality described above, since the direction or alignment of a multipole field generated for the correction is defined by the configuration of the electrode array. In general, however, an aberration correction in this way is also possible.

In accordance with one embodiment of the disclosure, the aberration correction unit has a further electrode array, wherein the further electrode array has a multiplicity of geometry-based correction electrodes each having m-fold rotational symmetry about the optical axis for multipole field generation, which are each controllable individually via a feed line; and
wherein the controller is designed to control the multiplicity of geometry-based correction electrodes of the further electrode array of the aberration correction unit individually for an aberration correction.

The at least one electrode array and the further electrode array can form a pair of electrode arrays which generate multipole fields of the same order of symmetry or order, but this need not be the case. To put it another way, n=m or else n/m can hold true.

In accordance with an embodiment of the disclosure, the aberration correction unit has one further electrode array or a plurality of further electrode arrays, the electrodes of which are embodied so as to be geometry-based and/or non-geometry-based. It is thus possible for different forms of realization of correction electrodes to be combined with one another within the aberration correction unit. If consideration is given to a sequence of correction electrodes for a first individual particle beam, for example, this sequence of electrodes can comprise both at least one geometry-based correction electrode and at least one non-geometry-based correction electrode. It is therefore possible to combine the aberration correction unit according to the disclosure with other aberration correction elements.

In accordance with one embodiment of the disclosure, the aberration correction unit has a further electrode array comprising segmented electrodes. Segmented electrodes are for example the multipole electrodes described above in connection with certain known systems, for example octupole electrodes or dodecapole electrodes. In this case, it is conceivable, for example, to combine different types of correction electrodes into pairs, the multipoles of which are aligned with one another in such a way that fundamental multipoles can be generated. It is conceivable, for example, for all cosine terms of a series expansion for multipole field generation to be generated by electrode arrays comprising geometry-based correction electrodes, and for all sine terms to be generated by correspondingly controlled multipole electrodes, or vice versa. In this case, it can be possible, by combining the multipole electrodes with the geometry-based correction electrodes, to reduce the number of poles in the multipole electrodes and thereby to reduce the control outlay at least somewhat; by way of example, it can be sufficient to provide a quadrupole segmented electrode instead of an octupole electrode, provided that a corresponding pairwise combination with a geometry-based correction electrode is effected within a specific sequence.

In accordance with an embodiment, the geometry-based correction electrodes of at least one electrode array of the aberration correction unit are for their part segmented, and the controller is designed to control these segments of the correction electrodes in turn individually. The geometry-based correction electrodes here are not circularly symmetrical, of course; this solution would be trivial and previously known. It is possible, for example, to segment for their part geometry-based correction electrodes having in each case at least 2-fold rotational symmetry about the optical axis for multipole field generation. The cross-section of a geometry-based correction electrode can thus be elliptic, for example, wherein individually controllable segments of the correction electrode, i.e. in general a multipole electrode embodied with a specific cross-section, are provided along this ellipse. It is also conceivable to insert correspondingly segmented electrodes into a geometry-based correction electrode. The various embodiment variants can have specific desirable features or undesirable features with regard to an aberration correction.

The various embodiments and aspects of the disclosure can be combined wholly or partly with one another, provided that no technical contradictions arise as a result.

### BRIEF DESCRIPTION OF THE DRAWINGS

The disclosure will be understood even better with reference to the accompanying figures, in which:

FIG. 1: schematically shows a multi-beam particle microscope;

FIG. 2: schematically shows an aberration correction in a multi-beam particle microscope using individually controllable segmented electrodes (here: octupole electrodes);

FIG. 3: schematically shows an array of octupole electrodes;

FIG. 4A-4D: schematically illustrates the generation of quadrupoles with varying orientation via an octupole electrode;

FIGS. 5A-5C: schematically show pairs of geometry-based electrodes for multipole generation according to the disclosure;

FIG. 6: schematically shows a geometry-based electrode for generating a focus shift;

FIG. 7: schematically shows a sequence of two geometry-based electrode arrays for quadrupole field generation;

FIG. 8: schematically shows a sequence of two geometry-based electrode arrays for quadrupole field generation;

FIG. 9: schematically shows a sequence of two geometry-based electrode arrays for quadrupole field generation;

FIG. 10: schematically shows a sequence of two geometry-based electrode arrays for hexapole field generation;

FIGS. 11A-11B: schematically show exemplary embodiments of geometry-based electrodes for quadrupole field generation;

FIGS. 12A-12B: schematically show exemplary embodiments of a pair of geometry-based correction electrodes for quadrupole field generation;

FIG. 13: schematically shows an exemplary embodiment of a sequence of a plurality of geometry-based electrode arrays for aberration correction;

FIG. 14: schematically shows one example of a decoupling of individual generated quadrupole fields;

FIG. 15: schematically illustrates a method for adjusting an aberration correction of a multi-beam particle microscope (orthogonalization); and

FIG. 16A-16C: schematically illustrate adjustment of optimum excitations/amplitudes of the geometry-based electrodes for optimizing imaging properties of the multi-beam particle microscope.

### DETAILED DESCRIPTION

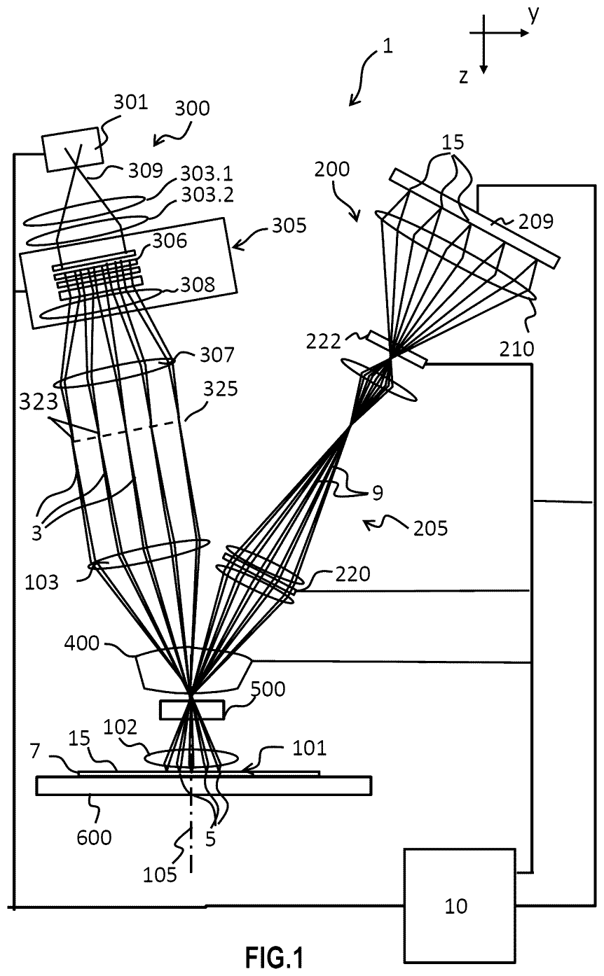

FIG. 1 schematically shows a multi-beam particle microscope 1. The multi-beam particle microscope 1 comprises a beam generating apparatus 300 with a particle source 301, for example an electron source. A divergent particle beam 309 is collimated by a sequence of condenser lenses 303.1 and 303.2, and impinges on a multi-aperture arrangement 305. The multi-aperture arrangement 305 comprises a plurality of multi-aperture plates 306 and a field lens 308. A multiplicity of individual particle beams 3 or individual electron beams 3 are generated by the multi-aperture arrangement 305. Midpoints of apertures in the multi-aperture plate arrangement are arranged in a field which is imaged onto a further field formed by beam spots 5 in the object plane 101. The pitch between the midpoints of apertures of a multi-aperture plate 306 can be 5 μm, 100 μm and 200 μm, for example. The diameters D of the apertures are smaller than the pitch of the midpoints of the apertures; examples of the diameter are 0.2 times, 0.4 times and 0.8 times the pitches between the midpoints of the apertures.

The multi-aperture arrangement 305 and the field lens 307 are configured to generate a multiplicity of focal points 323 of primary beams 3 in a grid arrangement on a surface 325. The surface 325 need not be a plane surface but rather can be a spherically curved surface in order to account for an image field curvature of the subsequent particle optical system.

The multi-beam particle microscope 1 further comprises a system of electromagnetic lenses 103 and an objective lens 102, which image the beam foci 323 from the intermediate image surface 325 into the object plane 101 with reduced size. In between, the first individual particle beams 3 pass through the beam switch 400 and a collective beam deflection system 500, via which the multiplicity of first individual particle beams 3 are deflected during operation and the image field is scanned. The first individual particle beams 3 incident in the object plane 101 for example form a substantially regular field, wherein pitches between adjacent incidence locations 5 can be 1 μm, 10 μm or 40 μm, for example. By way of example, the field formed by the incidence locations 5 can have a rectangular or hexagonal symmetry.

The object 7 to be examined can be of any desired type, for example a semiconductor wafer or a biological sample, and can comprise an arrangement of miniaturized elements or the like. The surface 15 of the object 7 is arranged in the object plane 101 of the objective lens 102. The objective lens 102 can comprise one or more electron optical lenses. By way of example, this can be a magnetic objective lens and/or an electrostatic objective lens.

The primary particles 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam switch 400 after the objective lens 102 and are supplied to a projection system 200. The projection system 200 comprises an imaging system 205 with first and second lenses 210 and 220, a contrast stop 222 and a multi-particle detector 209. Incidence locations of the second individual particle beams 9 on detection regions of the multi-particle detector 209 are located in a third field with a regular pitch from one another. Exemplary values are 10 μm, 100 μm and 200 μm.

The multi-beam particle microscope 1 furthermore has a computer system or control unit 10, which in turn can be embodied integrally or in multipartite fashion and which is designed both to control the individual particle optical components of the multi-beam particle microscope 1 and to evaluate and analyse the signals obtained by the multi-detector 209 or detection unit 209.

The sequence of multi-aperture plates 306, also called micro-optics, can also comprise the aberration correction unit of the multi-beam particle microscope according to the disclosure.

Further information relating to such multi-beam particle beam systems or multi-beam particle microscopes 1 and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated by reference in the present application.

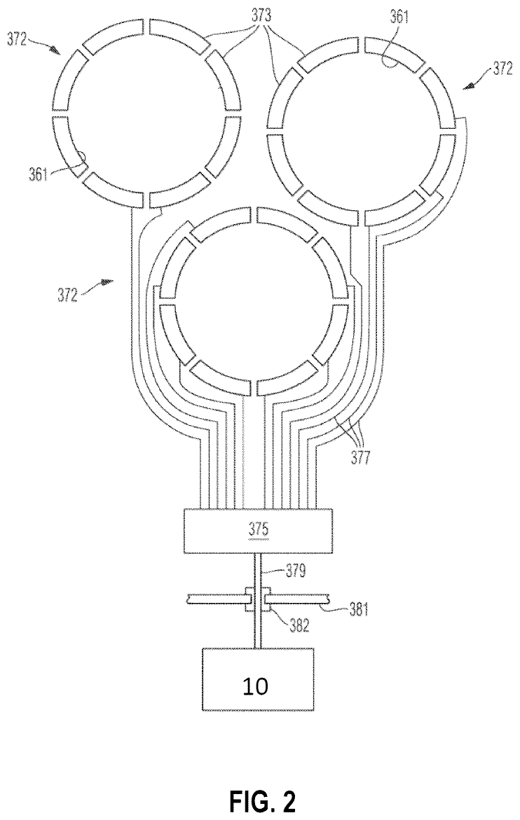

FIG. 2 schematically shows an aberration correction in a multi-beam particle microscope using individually controllable segmented electrodes. The aberration correction unit can be for example part of the micro-optics 306, as shown in FIG. 1. FIG. 2 illustrates by way of example a detail from an array of octupole electrodes 372 (see the figure and the control thereof in a schematic plan view). Each opening 391 in the array is assigned an octupole electrode 372 in order to generate for example a quadrupole field that acts on the individual particle beam passing through the opening 361. Each octupole electrode 372 has eight electrodes 373, which are arranged in a manner distributed around the opening 361 in the circumferential direction and which are controlled by the controller 10. For this purpose, in the example shown, an electronic circuit 375 which generates adjustable electrical voltages and feeds these to the electrodes 373 via lines 377 is arranged on a multi-aperture plate in a region arranged at a distance from the openings 361. FIG. 2 illustrates only a detail or part of the lines which supply the electrodes 372 with voltage; nevertheless, the problem of the very high number of lines in a narrowly delimited space is readily discernible. Moreover, the electronic circuit within the vacuum jacket 381 is exposed to particle bombardment and x-ray radiation, which adversely affects the service life of the electronic circuit 375.

The controller 10 controls the electronic circuit 375 by way of a serial data connection 379, which passes through a vacuum jacket 381 of the multi-beam particle microscope 1. Here, a seal 382 is provided, which seals the lines of the serial data connection 379 in relation to the vacuum jacket 381 of the multi-beam particle microscope 1. Providing a vacuum bushing for each individual one of the lines 377 would be impracticable owing to the large number of lines 377. The electronic circuit 375 generates the voltages fed to the electrodes 373 via the lines 377 depending on the data received from the controller 10 via the serial data connection 379. Consequently, the controller 10 is able to generate an electric quadrupole field in each of the openings 361, the field being adjustable in respect of its strength and its orientation about a centre of the opening 361. Using these quadrupole fields, it is possible to manipulate all of the individual particle beams 3 individually in each case. The controller 10 adjusts quadrupole fields for example in such a way that they cause in the beams 3 an astigmatism that compensates for an astigmatism brought about by the downstream optical system, such as the objective lens 102 in FIG. 1, for example, such that the beams are focused in a manner substantially free of astigmatism (stigmatically) in the object plane 101.

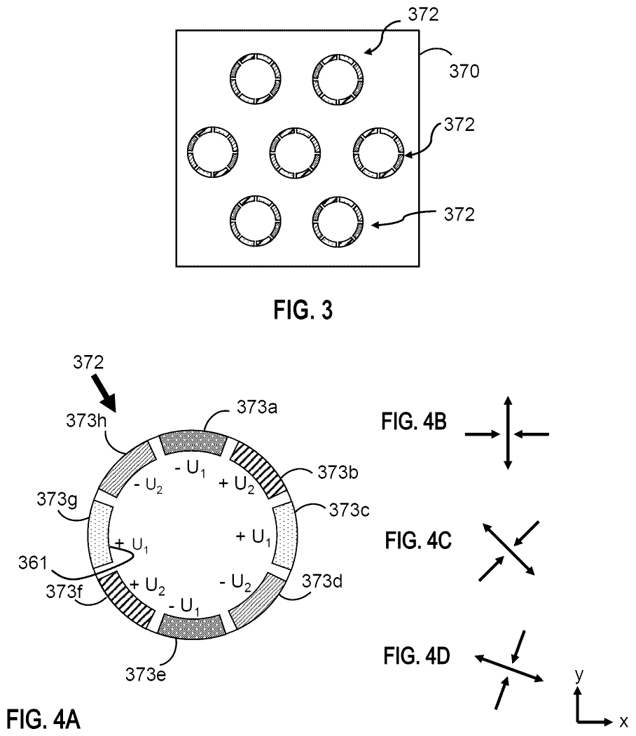

FIG. 3 schematically shows an array of octupole electrodes 372. In this case, the array of octupole electrodes 372 is arranged in a multi-aperture plate 370. Only seven octupole electrodes 372 are illustrated by way of example, but their number can be much higher, for example more than 100 octupole electrodes 372, which—as shown in FIG. 2—are controlled or supplied with voltage in each case.

FIGS. 4A-4D schematically illustrate the generation of quadrupole fields with varying orientation via an octupole electrode 372. The octupole electrode 372 has overall a round cross-section or a round opening 361. The octupole electrode 372 is segmented; the individual electrodes are designated by 373a to 373h. FIGS. 4A-4D then additionally illustrate what voltages are applied to each of the electrodes 373a to 373h. Identical voltages with regard to absolute value and sign are illustrated with the same hatching in FIGS. 4A-4D. The same voltage −U₁ is applied to each of the electrodes 373a and 373e; the voltage +U₁ is applied to each of the electrodes 373c and 373g. As a result, the octupole electrode 372 generates a first quadrupole field oriented along the axes x and y, as illustrated in FIG. 4B. The potential +U₂ is applied to each of the electrodes 373b and 373f; the potential −U₂ is applied to each of the electrodes 373d and 373h. As a result, these electrodes generate a second quadrupole field rotated by 45° compared with the first quadrupole field. This is illustrated in FIG. 4C. Both quadrupole fields together can generate—depending on the choice of the specific potentials +/−U₁ and +/−U₂—by way of superposition a resulting quadrupole field whose alignment is determined by the relative strength of the two quadrupole fields with respect to one another. Such a resulting quadrupole field is illustrated in FIG. 4D. By way of an appropriate choice of the potentials +/−U₁ and +/−U₂ or the amplitudes for quadrupole generation, it is thus possible to generate a resulting quadrupole field which can be oriented in any direction within the x-y-plane. The control of the octupole electrode 372 is complicated, however, and there is the added problem of accommodating lines in a very confined space when there is a multitude of octupole electrodes 372. In addition, it should be taken into consideration that aberrations occur as a result of the segmentation of the octupole electrodes 373a to 373h in the case of the generated resulting quadrupole field close to the electrodes; the boundary conditions are not smooth. As a consequence, it is desirable for a first individual particle beam 3 that passes through the segmented octupole electrode 372 not to be allowed to fly past the electrodes 373a to 373h too closely. In other words, a fill factor of the individual particle beam 3 passing through the octupole electrode 372 is comparatively small. The available space within the octupole electrode 372 cannot be utilized optimally. Space utilization would be better in conjunction with a larger fill factor if more poles were provided at the multipole corrector 372, for example twelve poles 373; however, implementing this can turn out to be even worse owing to the described confinement in the arrangement of the lines 377 in a multi-aperture plate 370.

According to the disclosure, the potential used for an aberration correction for each individual particle beam 3 is now no longer generated via a single multipole corrector per individual particle beam 3. Instead, for each individual particle beam 3 a sequence of geometry-based electrodes is used for generating the correction potential. In this case, these geometry-based electrodes are each individually controllable and each use only exactly one feed line, which reduces the number of feed lines, for example within a multi-aperture plate, and thus also the control outlay for the control of the electrodes. What is of interest here for the respective multipole generation in the sequence composed of geometry-based electrodes is the shape of these electrodes.

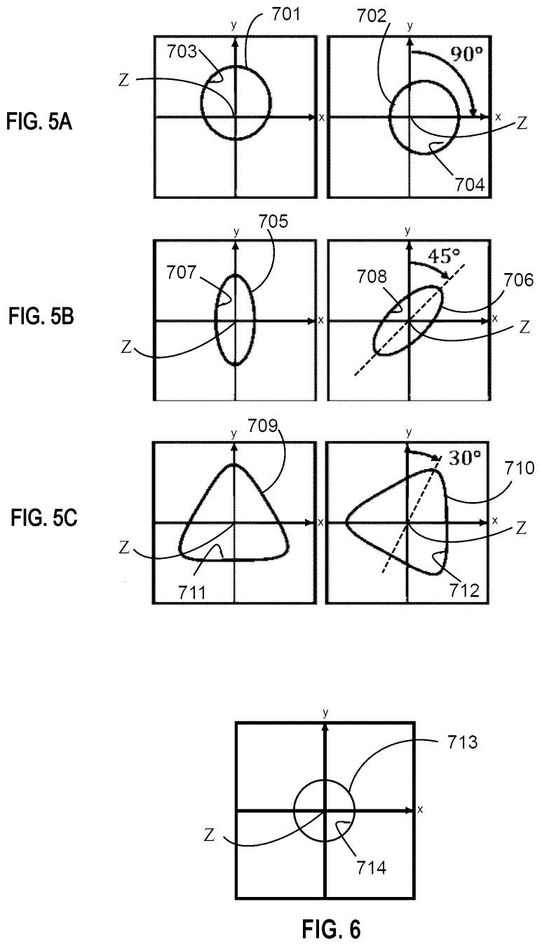

FIGS. 5A-5C show a feature in this case. The illustration schematically shows a plurality of pairs of geometry-based electrodes for multipole generation according to the disclosure. Consideration is given once again to equation (1): U∝U₀+U₁ cos (φ+φ₁)+U₂ cos (2φ+φ₂)+U₃ cos (3φ+φ₃)+ . . . .

For an aberration correction it is thus desirable to generate a dipole field with desired orientation, a quadrupole field with desired orientation, a hexapole field with desired orientation, etc.

FIG. 5A shows a sequence of geometry-based correction electrodes 701 and 702 for the generation of a dipole field. FIG. 5B shows two geometry-based correction electrodes 705 and 706 for the generation of a quadrupole field. FIG. 5C shows two geometry-based correction electrodes 709 and 710 for the generation of a hexapole field. The geometry-based correction electrode 713 with a round cross-section in accordance with FIG. 6 can be used for generating the offset potential U₀.

The electrode arrangement illustrated in FIG. 5B will be described in greater detail first, specifically for reasons of clarity and owing to the good comparability with the superposed quadrupole fields in accordance with FIGS. 4A-4D. Instead of a quadrupole field being generated by a crosslike arrangement and corresponding application of voltage for electrodes 373a, 373c, 373e and 373g, an identical quadrupole field can also be generated by an electrode with a specific cross-section. This is a cross-sectionally elliptic electrode, as is illustrated by way of example by the electrode 705 on the left in FIG. 5B. Its opening 707 is elliptic and it is aligned centrally with respect to the optical axis Z. The semi-major axis of the ellipse is oriented along the y-axis in this case. In this case, the elliptic shape extends somewhat along the optical axis Z (here: into the plane of the drawing), although this extent is typically only a few μm. The geometry-based correction electrode 705 with an elliptic cross-section has 2-fold rotational symmetry about the optical axis Z. The ellipse can be mapped onto itself by being rotated about the optical axis Z by 180°. The geometry-based correction electrode 706 illustrated on the right in FIG. 5B likewise has an elliptic cross-section or a correspondingly shaped opening 708. This of course also has 2-fold rotational symmetry about the optical axis Z, but it is oriented differently from the geometry-based correction electrode 705: The major axis of the ellipse describes an angle of 45° with the y-axis. A quadrupole field generated via the geometry-based correction electrode 706 is therefore rotated by substantially 45° with respect to the quadrupole field generated via the geometry-based correction electrode 705. If an individual particle beam 3 then passes through the electrodes 705 and 706 in succession, the individual particle beam 3 experiences the effect of two quadrupole fields, the resulting effect of which corresponds to an effective quadrupole field (analogously to the situation in FIG. 4D). Each of the geometry-based correction electrodes of the pair 705 and 706 is supplied with voltage by only one feed line in each case. The amplitude of this excitation can be chosen individually. It is thus possible for the effect of an effective quadrupole field with arbitrary or adjustable orientation also to be generated by way of the sequence or the pair of geometry-based correction electrodes 705, 706 having 2-fold rotational symmetry.

The situation regarding other multipole fields turns out to be totally analogous: FIG. 5C shows a pair of geometry-based correction electrodes 709 and 710 having 3-fold rotational symmetry about the optical axis Z. The geometry-based correction electrodes 709 and 710 have the same shape, but are oriented differently. The shape with 3-fold symmetry can be described by an equilateral triangle having rounded corners. A hexapole field can be generated by this type of geometry-based electrodes. The angle of rotation by which the two geometry-based correction electrodes 709 and 710 of the pair are rotated relative to one another is substantially

$$\frac{90 °}{order of symmetry} ,$$

i.e. here

$$\frac{9 {0}^{∘}}{3} = 30 ° .$$

FIG. 5A shows a pair of geometry-based correction electrodes 701, 702 which can be used to generate the effect of an effective dipole field with arbitrary orientation. In this case, the two geometry-based correction electrodes 701 and 702 are embodied so as to be round in cross-section (cf. openings 703 and 704), but they are not arranged centrally in relation to the optical axis Z. Therefore, there is no rotational symmetry in relation to the optical axis Z; formally, the geometry-based correction electrodes 701 and 702 thus have 1-fold symmetry. The angle of rotation about the optical axis Z is

$$\frac{90 °}{1} = 90 ° .$$

Here, too, the geometry-based correction electrodes 701 and 702 can each be supplied with voltage individually; according to the applied voltages or amplitudes, it is possible to generate the effect of an effective dipole field with arbitrary orientation.

FIGS. 5A-5C show only pairs of geometry-based correction electrodes by way of example. A multiplicity of corresponding pairs of geometry-based correction electrodes can be used to form electrode arrays having a corresponding multiplicity of geometry-based correction electrodes.

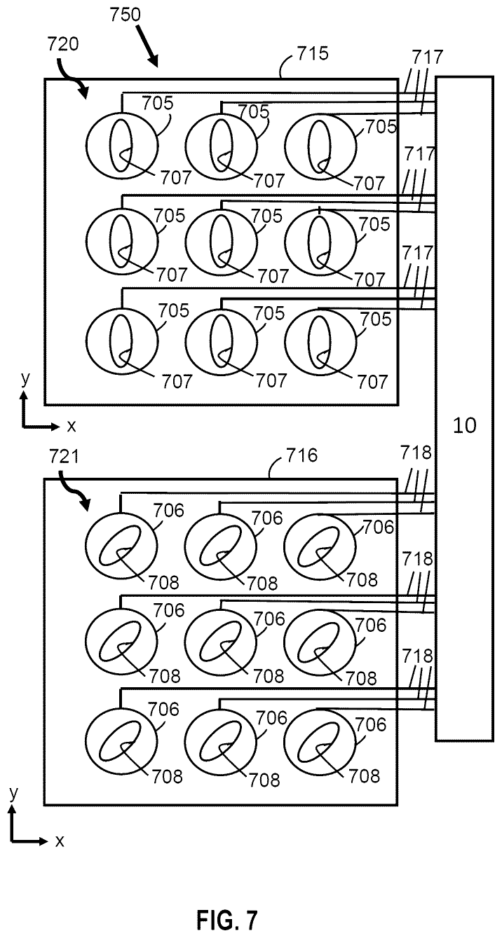

FIG. 7 schematically shows a sequence of two geometry-based electrode arrays 720, 721 for quadrupole generation. In this case, the first electrode array 720 is integrated into a multi-aperture plate 715. The second electrode array 721 is integrated into a multi-aperture plate 716. The geometry-based correction electrodes 705 of the first electrode array 720 and the geometry-based correction electrodes 706 of the second electrode array 721 each have 2-fold rotational symmetry about the optical axis Z of the particle optical beam path of each individual particle beam 3. In the example shown, the orientation of the geometry-based correction electrodes 705 embodied so as to be elliptic in cross-section in the first multi-aperture plate 715 is identical in each case; the same analogously applies to the geometry-based correction electrodes 706 in the second multi-aperture plate 716. Each electrode 705 and 706 is supplied with voltage by an individual line 717 and 718, respectively. In this case, the controller 10 is designed to control the multiplicity of geometry-based correction electrodes 705, 706 of the first electrode array 720 and of the second electrode array 721 of the aberration correction unit 750 individually for an aberration correction. This can of course also be effected by a corresponding subunit or by a component of the controller 10. By way of the individual control of each of the geometry-based correction electrodes 705, 706 (18 individually controllable lines 717, 718 in total), a field-dependent aberration correction is possible for a multiplicity of individual particle beams 3.

In the case of the aberration correction unit 750, only one pair of electrode arrays 720, 721 is provided in the example shown. However, it is of course also possible to provide a further pair or a plurality of further pairs of electrode arrays in order to generate multipoles of a different order or to carry out further aberration corrections. In this respect, FIG. 7 should be understood to be merely by way of example. The aberration correction unit is however suitable for an astigmatism correction, for example. It is clear, incidentally, that the sequence of the two electrode arrays 720 and 721 is not illustrated correctly in perspective in FIG. 7. In actual fact, the two electrode arrays 720 and 721 are arranged one below the other in such a way that, in the example shown, an array with nine first individual particle beams 3 passes firstly through the nine openings 707 of the first electrode array 720 and then through the nine openings 708 of the second electrode array 721. A further element or component parts can also be arranged between the two multi-aperture plates 715 and 716 with the respective electrode arrays 720 and 721, but this need not be the case. The significance of further passive multi-aperture plates between electrode arrays will be discussed in even greater detail further below.

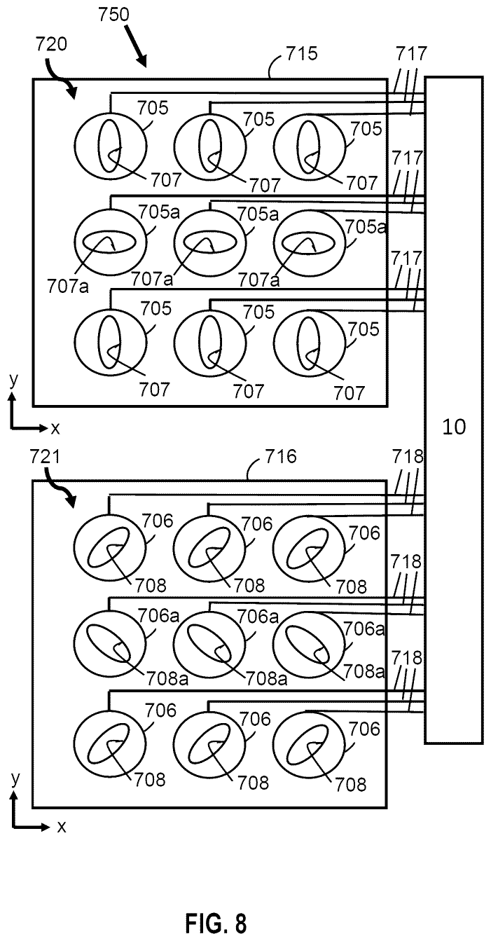

FIG. 8 schematically shows a further sequence of two geometry-based electrode arrays 720 and 721 for quadrupole generation or astigmatism correction. In this case, as always, the same reference signs designate the same elements. The illustration in FIG. 8 largely corresponds to the illustration in FIG. 7. However, the alignment of the cross-sectionally elliptic electrodes 705, 706 within the respective electrode arrays 720 and 721 is somewhat different: Within the electrode array 720, the geometry-based correction electrodes 705 are oriented identically only row by row. Correspondingly, the geometry-based correction electrodes 706 in the second electrode array 721 are also aligned identically only row by row. Nevertheless, it holds true in this embodiment variant, too, that the geometry-based correction electrodes 705, 705a in the first electrode array 720 are rotated relative to associated geometry-based correction electrodes 706, 706a in the second electrode array 721 in relation to the optical axis Z by the same angle, namely by substantially 45° in each case. Since the geometry-based correction electrodes are controlled individually via the controller 10 anyway, in general only the pairwise orientation of mutually associated geometry-based correction electrodes 705, 706 and respectively 705a, 706a is desirable.

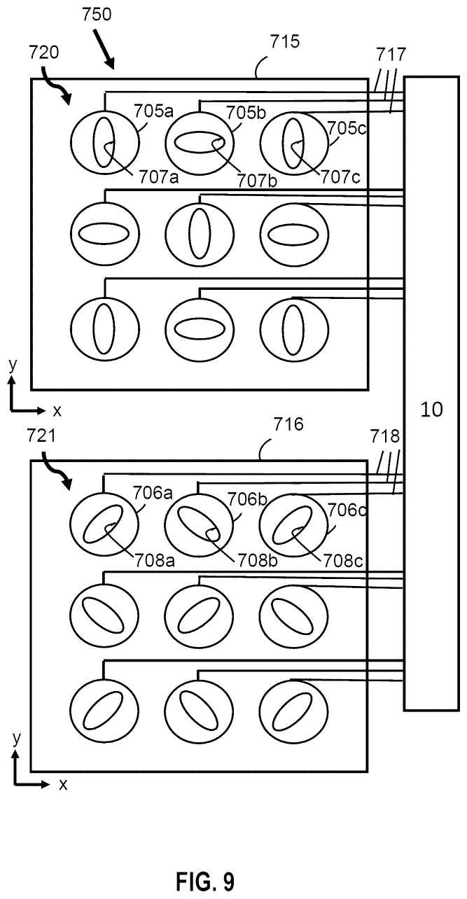

FIG. 9 schematically shows a further sequence of two geometry-based electrode arrays 720, 721 for quadrupole generation or astigmatism correction. Compared with the illustrations in FIG. 7 and FIG. 8, the alignment of the individual geometry-based correction electrodes within the respective electrode arrays 720 and 721 or within the multi-aperture plates 715, 716 is somewhat even more complex: Within the respective electrode array 720, 721, the alignment of the cross-sectionally elliptic electrodes 705a, 705b and 705c illustrated varies both row by row and column by column. In relation to pairs of geometry-based correction electrodes, i.e. for example the electrodes 705a and 706a, as well as 705b and 706b, 705c and 706c, it again holds true, however, that the geometry-based correction electrodes in the first electrode array 720 are rotated relative to their associated geometry-based correction electrodes in the second electrode array 721 in relation to the optical axis Z once again by the same angle in each case (here: 45°).

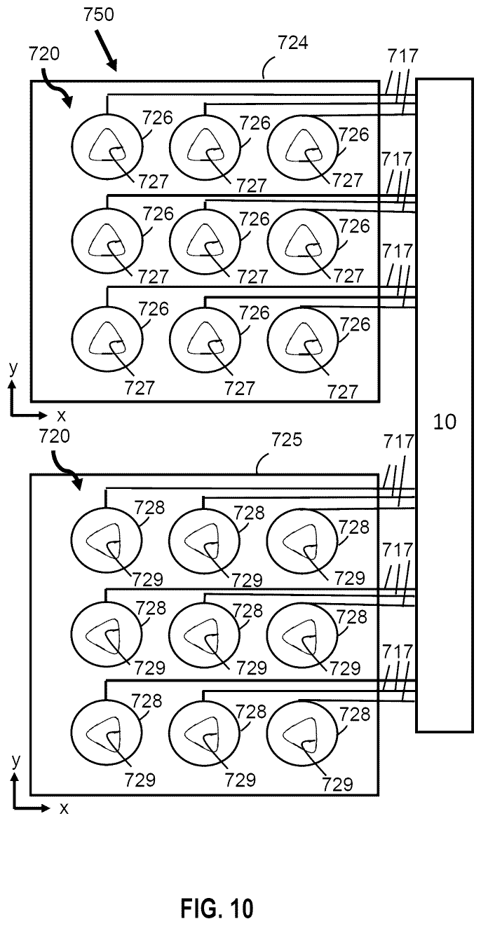

FIG. 10 schematically shows a sequence of two geometry-based electrode arrays 722, 723 for hexapole field generation or for the correction of an aberration of individual particle beams 3 that has 3-fold symmetry. In this case, the first electrode array 722 is integrated into a first multi-aperture plate 724. The second electrode array 723 is integrated into a second multi-aperture plate 725. The geometry-based correction electrodes 726 and 728 respectively have 3-fold rotational symmetry about the optical axis Z for hexapole field generation. In this case, the openings 727 and 729 of the respective electrodes 726, 728 are embodied substantially as a rounded equilateral triangle. The orientation of the geometry-based correction electrodes 726 in the first electrode array 722 is identical in each case. In addition, the orientation of the geometry-based correction electrodes 728 in the second electrode array 723 is likewise identical. Overall, however, the geometry-based correction electrodes 726 in the first electrode array 722 are rotated relative to associated geometry-based correction electrodes 728 in the second electrode array 723 in relation to the optical axis Z in each case by the same angle (here: 30° owing to the 3-fold order of symmetry). The controller 10 is again designed to control the multiplicity of geometry-based correction electrodes 726, 728 of the first electrode array 722 and of the second electrode array 723 of the aberration correction unit 750 individually for an aberration correction. Of course, it is possible for the orientation of the geometry-based correction electrodes 726, 728 within the electrode arrays 722, 723 also to be made variable, as has been described in connection with the geometry-based correction electrodes having 2-fold symmetry in FIGS. 8 and 9. In any event, however, the fixed rotational relationship holds true for each associated pair of geometry-based correction electrodes 726 and 728. Here, too, it is of course possible for the aberration correction unit 750 to have further correction elements and for example further electrode arrays, which are not illustrated in this way in FIG. 10.

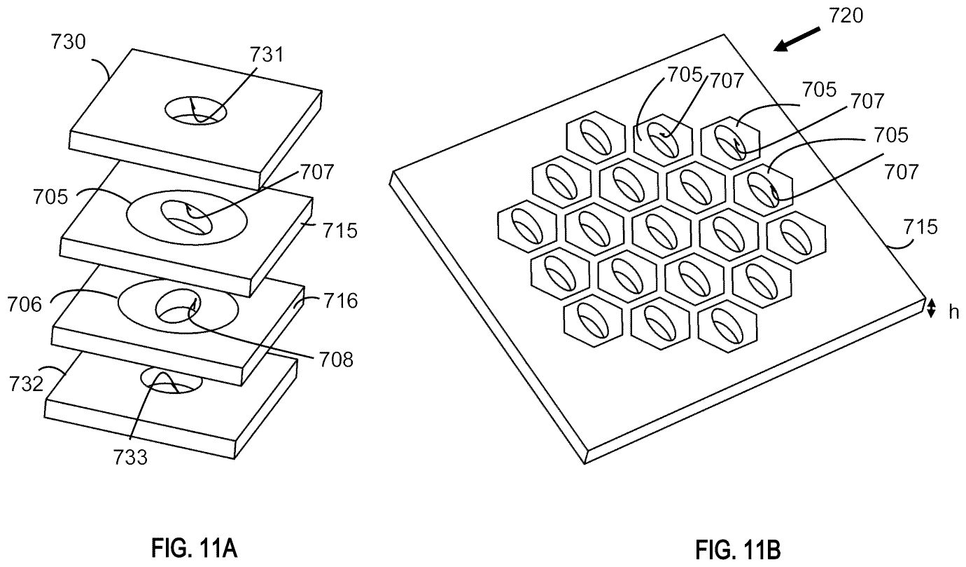

FIGS. 11A-11B schematically show exemplary embodiments of geometry-based electrodes for quadrupole field generation in a perspective illustration. FIG. 11A shows by way of example merely a sequence of geometry-based correction electrodes; in this case, each of the electrodes can be part of a corresponding array of electrodes, each of the electrodes of the array being individually controllable. The exemplary embodiment in FIG. 11A shows a sequence of four multi-aperture plates 730, 715, 716 and 732. In this case, the multi-aperture plates 730 and 732 are standard multi-aperture plates having a multiplicity of passive round apertures arranged, in relation to the direction of the particle optical beam path, upstream and respectively downstream of the multi-aperture plates 715, 716 with individually controllable geometry-based correction electrodes 705, 706. In the exemplary embodiment illustrated, the geometry-based correction electrodes 705, 706 themselves are integrated into the multi-aperture plates 715, 716 or extend through the corresponding openings 707, 708 of the multi-aperture plates 715, 716. In this case, a flat, conductive part of the electrodes 705, 706 is additionally provided on the top side substantially flush with the surface of the multi-aperture plates 715, 716, at which part it is possible for the electrodes 705, 706 to make contact with a respective feed line. In the example shown, the conductive surface has a circular outer contour, but it could also be shaped differently in terms of its outer contour.

An alternative exemplary embodiment is illustrated by way of example in FIG. 11B. FIG. 11B shows by way of example just one multi-aperture plate 715, but in return the entire electrode array 720. The geometry-based correction electrodes 705 are again elliptic in cross-section and extend through the thickness h of the multi-aperture plate 715. In this case, a typical thickness of the multi-aperture plate is a few μm, for example 5, 10, 20 or 30 μm. The orientation of the electrodes 705 is uniform within the multi-aperture plate 715 and each of the electrodes 705 can again be controlled individually (corresponding feed lines are not illustrated explicitly in the figure). The conductive surface of the geometry-based correction electrodes 705, the surface being provided on the top side of the multi-aperture plate 715 for contact-making purposes, is embodied so as to be hexagonal in the example shown. This shaping allows the individual geometry-based electrodes 705 to be regularly spaced apart from one another and is comparatively simple to produce. In the case of both embodiments shown in FIGS. 11A-11B, it holds true that the geometry-based electrodes 705, 706 are insulated from the multi-aperture plates 715 and 716.

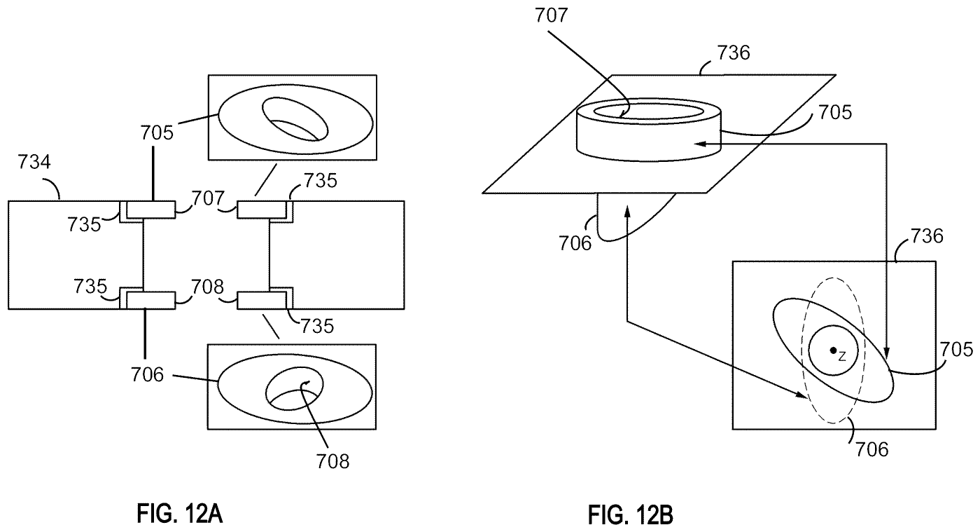

FIGS. 12A-12B schematically show other embodiments of a pair of geometry-based correction electrodes for quadrupole field generation. FIG. 12A shows a carrier plate 734, into which the first geometry-based correction electrode 705 is incorporated on the top side and the second geometry-based correction electrode 706 is incorporated on the underside. Each of the electrodes 705, 706 is insulated from the carrier plate 734 via an insulator 735 and is individually controllable. In this constructional embodiment variant, too, it holds true that the two geometry-based correction electrodes 705 and 706 of each pair of geometry-based correction electrodes are rotated relative to one another about the optical axis Z, specifically by 45° in the example shown.

FIG. 12B shows an alternative constructional configuration with a carrier plate 736, on the top side of which the geometry-based correction electrode 705 is arranged and on the underside of which the geometry-based correction electrode 706 is arranged. Here, too, the two electrodes 705, 706 are insulated from the carrier plate 736. The alignment of the two elliptic correction electrodes 705, 706 is again rotated relative to one another about the optical axis, specifically once again at an angle of substantially 45°, as is indicated in the geometric drawing at the bottom right in FIG. 12B.

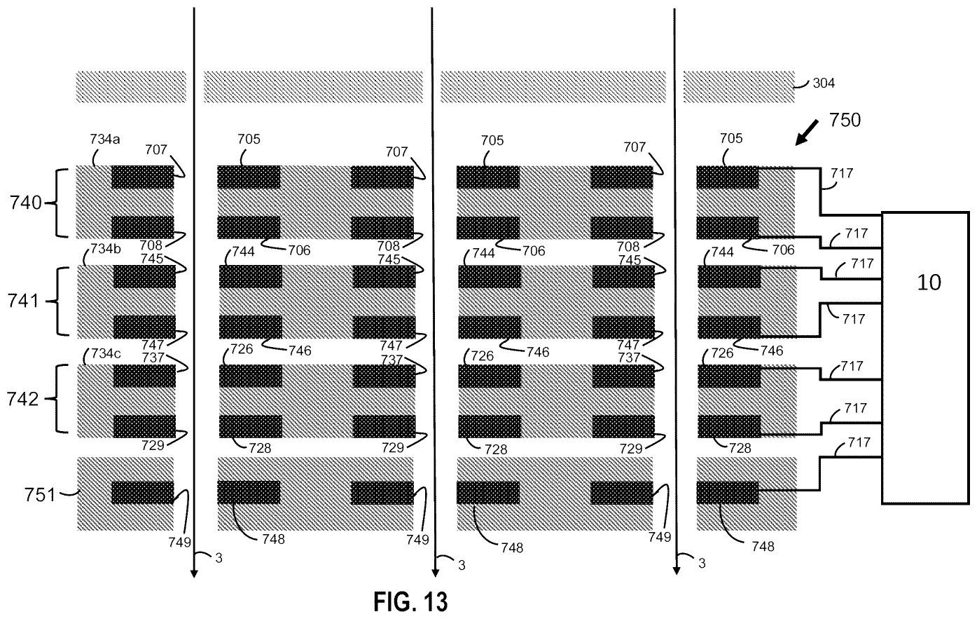

FIG. 13 schematically shows a further exemplary embodiment of an aberration correction unit 750 with a sequence of a plurality of geometry-based electrode arrays for aberration correction. In the exemplary embodiment shown, the aberration correction unit 750 is embodied as part of micro-optics 306. A multi-aperture plate 304 (filter plate) for generating the first individual particle beams 3 is also illustrated schematically.

The aberration correction unit 750 comprises three pairs of electrode arrays: The first pair 740 comprises a first electrode array having geometry-based correction electrodes 705, and a second electrode array having geometry-based correction electrodes 706. In this case, the two arrays are incorporated into a carrier plate 734a, as has already been explained in more specific detail in association with FIG. 12A. In the example shown, the geometry-based correction electrodes 705 and 706, which in each case form mutually associated pairs and through which the same individual particle beam 3 passes, are embodied so as to be elliptic in cross-section, the semi-axes of the ellipses being rotated relative to one another substantially by 45°. Each of the geometry-based correction electrodes 705, 706 is individually controlled by the controller 10 via an individual feed line 717. In FIG. 13, the corresponding lines 717 are depicted only by way of example for a beam 3 passing on the far right-hand side. In this way, via the first pair 740 of electrode arrays, for the first individual particle beams 3, a quadrupole field with arbitrary orientation can be generated in each case individually in order to correct an astigmatism of the individual particle beams 3.

A second pair 741 of electrode arrays is arranged downstream of the first pair 740 along the particle optical beam path, the second pair having geometry-based correction electrodes 744, 746 in the example shown. The latter are embodied so as to be substantially round in cross-section in the example shown and the round correction electrodes 744, 746 in each pair are displaced relative to one another orthogonally with respect to the optical axis Z in different directions by approximately 90°. The controller 10 is again configured to control the round correction electrodes 744, 746 individually. For example, a static distortion of the second field of first individual particle beams 3 upon incidence in the object plane 101 can be corrected in this case.

A third pair 742 of electrode arrays having geometry-based correction electrodes 726, 728 is arranged downstream of the second pair 741 in the direction of the particle optical beam path. In the example shown, the correction electrodes 726, 728 have 3-fold rotational symmetry and are rotated relative to one another in pairs about the optical axis Z by substantially 30°. As a result, a hexapole field for correcting an aberration having 3-fold symmetry can be formed individually for each first individual particle beam 3.

Downstream of the third pair 742 of electrode arrays, provision is made for a multi-aperture plate 751 with an electrode array having a multiplicity of geometry-based correction electrodes 749 which have a round cross-section and which are arranged in a centred fashion relative to the respective optical axis Z. In this case, the controller 10 is furthermore designed to control the multiplicity of geometry-based correction electrodes 749 of this further electrode array individually substantially for correcting a focus position of the first individual particle beams 3. A correction of the focus position can be used for example for image field curvature correction and/or image field inclination correction.

The order of the first pair 740, the second pair 741, the third pair 742 and the multi-aperture plate 751 with the further electrode array, as illustrated in FIG. 13, should be understood to be merely by way of example in this case. It is possible for the order of these elements to be interchanged. Moreover, it is not absolutely necessary for the respective pairs of electrode arrays 740, 741, 742 to be embodied as directly successive electrode arrays. Instead, it would also be conceivable to arrange firstly the first electrode arrays of each pair and only thereafter the second electrode arrays of each pair. From a constructional standpoint, too, other configurations are possible, of course; some of them have already been described by way of example further above in this patent application.

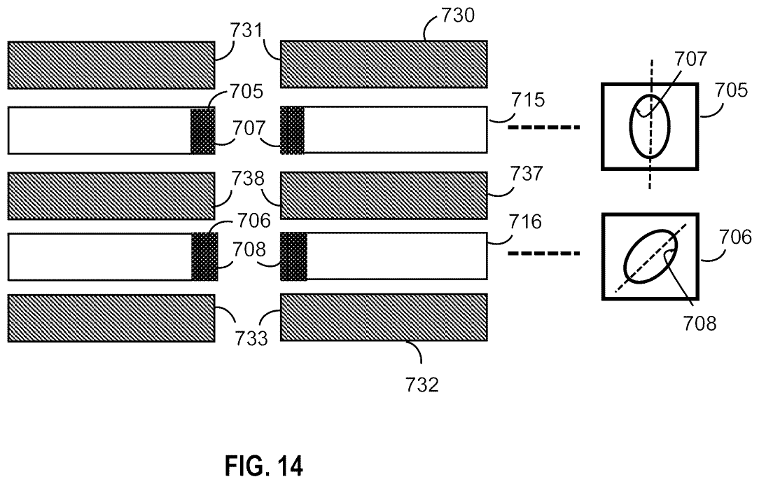

FIG. 14 shows by way of example an embodiment of the disclosure which makes it possible to generate quadrupole fields which are linearly independent of one another. In general, two geometry-based correction electrodes per generated multipole field are used in order to realize arbitrary alignments of this multipole field. In line with the concept of the series expansion, a cosine term (cos n φ) is realized via one geometry-based electrode and a sine term (sin n φ) of the desired multipole field is realized via the other geometry-based electrode. The two terms describe the fundamental multipoles or multipole fields. The angle between the two fundamental multipoles is dependent on the order of the multipole and is 90°/n. If the angle between the generated multipoles is exactly 90°/n, then optimum excitations of the geometry-based correction electrodes of a pair are independent of one another. Strictly speaking, however, it is the case that the orientation of a quadrupole field generated by the application of a potential U₁ to the geometry-based correction electrode varies along the axial z-position. Charged particles of the individual particle beam 3 which pass through the geometry-based correction electrodes therefore experience an effective quadrupole field which is rotated (for example cos (2φ+φ) instead of cos (2φ)). The same correspondingly applies to a quadrupole generated by the application of a potential U₂ at the second geometry-based correction electrode of a pair of electrodes; this quadrupole can no longer be described by a pure sine term. For this reason, the angle between the two quadrupoles is no longer exactly 45°. In accordance with one embodiment of the disclosure, this deviation can be corrected by virtue of the fact that a standard multi-aperture plate having a multiplicity of passive round apertures is arranged between mutually adjacent multi-aperture plates with, integrated therein, electrode arrays having individually controllable geometry-based correction electrodes.

A corresponding embodiment or a detail from a corresponding aberration correction unit 750 is illustrated in FIG. 14. A multi-aperture plate 730 having circular openings 731 is arranged upstream of the first electrode array having the geometry-based correction electrodes 705. Furthermore, a further multi-aperture plate 737 having circular openings 738 is arranged between the first electrode array having the correction electrodes 705 and the second electrode array having the geometry-based correction electrodes 706. Likewise, a further multi-aperture plate 732 having circular openings 733 is arranged downstream of the second electrode array having the geometry-based correction electrodes 706. The standard multi-aperture plates 730, 737 and 732 are each earthed and serve as counterelectrodes. The quadrupole fields generated by the electrodes 705 and respectively 706 are oriented exactly by 45° with respect to one another. The orientation of the quadrupoles generated thus corresponds exactly to the orientations of the electrode openings 707 and respectively 708.

For reasons of illustrative simplicity, the exemplary embodiment illustrated in FIG. 14 relates once again to quadrupole generation for the purpose of aberration correction. However, the described concept of providing standard multi-aperture plates having circular openings in each case upstream of the sequence of electrode arrays and between different electrode arrays is of course also applicable to other geometry-based correction electrodes and sequences thereof for the purpose of aberration correction. Accordingly, a respective standard multi-aperture plate is then also arranged between such electrodes which generate multipoles of a varying order.

An alternative solution for producing linear independence of generated multipoles pursues the path of altering the angle of rotation between the geometry-based correction electrodes of a pair of electrode arrays, as a result of which the multipoles thus produced do not mix or are orthogonal. However, it is then nevertheless possible for such an arrangement to generate additional multipoles of a different, or higher, order that would not arise in this way in the case of an exact rotation by 90°/n of the correction electrodes.

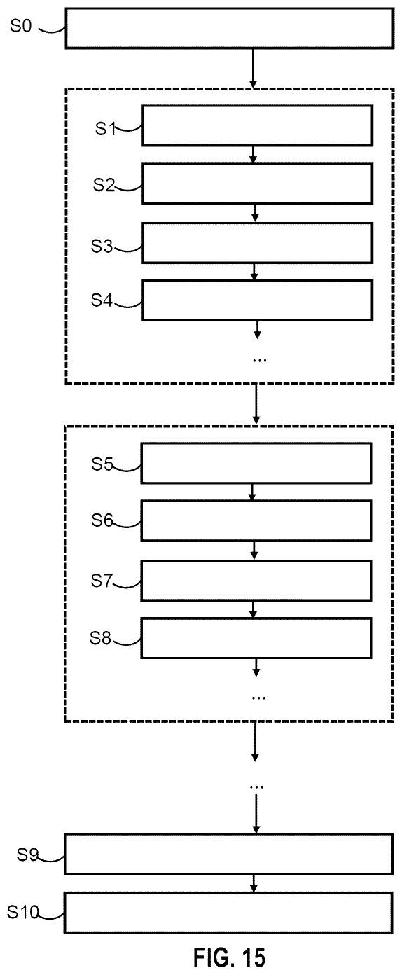

A further solution approach is to generate suitable linear combinations of excitations of the geometry-based correction electrodes so that the fundamental multipoles are prevented from mixing. FIG. 15 schematically illustrates a method for generating fundamental multipoles for an aberration correction in a multi-beam particle microscope 1. An initial method step S0 involves providing a multi-beam particle microscope 1 having an aberration correction unit 750 according to the disclosure, as described above in a plurality of embodiment variants.

A method step S1 involves only exciting a first geometry-based correction electrode of a sequence of correction electrodes. As a result of this excitation, what arises is not exclusively the desired multipole, rather further multipoles are additionally generated as well, albeit with significantly weaker amplitude.

A further method step S2 involves determining the amplitude of the first multipole thus generated. A further method step S3 involves determining the amplitude of the second multipole thus generated, and a method step S4 involves determining the amplitude of the third multipole thus generated, etc. This is continued until the amplitudes of all the multipoles thus generated have been determined.

Then, in a method step S5, only the second geometry-based correction electrode of the sequence is excited. This second geometry-based correction electrode, too, normally generates not only the desired multipole, but also further parasitic multipoles. Accordingly, in accordance with the present method, a method step S6 involves determining the amplitude of the first multipole generated, a method step S7 involves determining the amplitude of the second multipole thus generated, and a method step S8 involves determining the amplitude of the third multipole thus generated, etc. This is continued until all the amplitudes of all the multipoles thus generated have been determined. Afterwards, exclusively the third or generally next geometry-based correction electrode of a sequence is excited, etc.

A method step S9 involves establishing an amplitude matrix on the basis of the ascertained amplitudes. A method step S10 involves inverting the amplitude matrix. The amplitude matrix describes the relationship between the excitations of the correction electrodes and the amplitudes of the fundamental multipoles generated. Via the inverted amplitude matrix, it is possible to directly alter amplitudes of fundamental multipoles, without the proportion of other fundamental multipoles being altered by this control change. The geometry-based correction electrodes can thus be excited on the basis of the entries in the inverted amplitude matrix, wherein fundamental multipoles can be generated in a targeted manner. In this way, for example, a previously known field dependence of aberrations can be corrected in a targeted manner.

Of course, the method described can be carried out for all the sequences of the geometry-based correction electrodes. In other words, the method is carried out for each of the first individual particle beams and the aberration correction unit is adjusted for all of the individual particle beams.

The following equations (2) and (3) describe once again the relationships between the amplitudes of the fundamental multipoles generated and the excitations of the geometry-based correction electrodes:

$$A * ( \begin{matrix}Excitation 1 \\ Excitation 2 \\ Excitation 3 \\ Excitation 4 \\ …\end{matrix} ) = ( \begin{matrix}Amplitude cos ( φ ) \\ Amplitude sin ( φ ) \\ Amplitude cos ( 2 * φ ) \\ Amplitude sin ( 2 * φ ) \\ …\end{matrix} ) \qquad equation ( 2 )$$

$${A}^{- 1} * ( \begin{matrix}Amplitude cos ( φ ) \\ Amplitude sin ( φ ) \\ Amplitude cos ( 2 * φ ) \\ Amplitude sin ( 2 * φ ) \\ …\end{matrix} ) = ( \begin{matrix}Excitation 1 \\ Excitation 2 \\ Excitation 3 \\ Excitation 4 \\ …\end{matrix} ) \qquad equation ( 3 )$$

In this case, A denotes the amplitude matrix and A-1 denotes the inverted amplitude matrix.

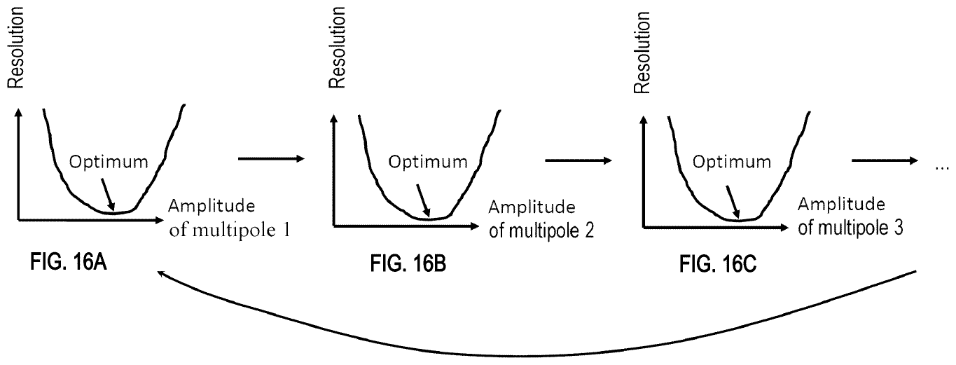

One desirable property of the method described above resides in the decoupling of the generated multipoles. This in turn is desirable in the optimization of a particle optical property of the multi-beam particle beam system or multi-beam particle microscope 1. It is possible for example to optimize the resolution. Since the optimum amplitudes of each generated multipole are independent of one another to a first approximation, the amplitudes of these multipoles can also be optimized one after the other independently of one another. In this case, the amplitude is varied and the imaging properties are measured in each case. FIGS. 16A-16C show this process pictorially. Firstly, the amplitude of multipole 1 is varied and the respective resolution is determined. An optimum amplitude of the first multipole is ascertained as a result. Subsequently or independently thereof, the amplitude of the second multipole can be varied, the resolution is measured in each case and the optimum is determined. Subsequently, the amplitude of the third multipole is varied and the resolution is determined in each case in order to obtain the corresponding optimum for the amplitude of the third multipole. This can be continued for each multipole. It is also possible to repeat this process a few times in order to decouple remaining dependencies between the amplitudes of different multipoles.

The explanations above have been given substantially in relation to a multi-beam particle microscope 1. However, they are of course also valid for a different type of multi-beam particle beam system in which a corresponding aberration correction unit can likewise be used.

Moreover, it is possible to combine the aberration correction unit according to the disclosure with other aberration correction elements or else in part to replace elements according to the disclosure with other elements. In accordance with one embodiment of the disclosure, besides at least one geometry-based electrode array, the aberration correction unit comprises a further electrode array comprising segmented electrodes. Segmented electrodes are for example the multipole electrodes described above in connection with certain known systems, for example octupole electrodes or dodecapole electrodes. In this case, it is conceivable, for example, to combine different types of correction electrodes into pairs, the multipoles of which are aligned with one another in such a way that fundamental multipoles can be generated. It is conceivable, for example, for all cosine terms of a series expansion for multipole field generation to be generated by electrode arrays comprising geometry-based correction electrodes, and for all sine terms to be generated by correspondingly controlled multipole electrodes, or vice versa. In this case, it can be possible, by combining the multipole electrodes with the geometry-based correction electrodes, to reduce the number of poles in the multipole electrodes and thereby to reduce the control outlay at least somewhat; by way of example, it can be sufficient to provide a quadrupole segmented electrode instead of an octupole electrode, provided that a corresponding pairwise combination with a geometry-based correction electrode is effected within a specific sequence.

In accordance with an embodiment, the geometry-based correction electrodes of at least one electrode array of the aberration correction unit are for their part segmented, and the controller is designed to control these segments of the correction electrodes in turn individually. The geometry-based correction electrodes here are not circularly symmetrical, of course; this solution would be trivial and previously known. It is possible, for example, to segment for their part geometry-based correction electrodes having in each case at least 2-fold rotational symmetry about the optical axis for multipole field generation. The cross-section of a geometry-based correction electrode can thus be elliptic, for example, individually controllable segments of the correction electrode, i.e. in general a multipole electrode embodied with a specific cross-section, being provided along this ellipse. It is also conceivable to insert correspondingly segmented electrodes into a geometry-based correction electrode. The various embodiment variants can have specific desirable features or undesirable features with regard to an aberration correction.

Example 1: Multi-beam particle microscope, having the following features:
a multi-beam generator configured to generate a first field of a multiplicity of charged first individual particle beams;
a first particle optical unit with a first particle optical beam path, configured to image the generated first individual particle beams onto a sample surface in the object plane such that the first individual particle beams are incident on the sample surface at incidence locations, which form a second field;
a detection system with a multiplicity of detection regions that form a third field;
a second particle optical unit with a second particle optical beam path, configured to image second individual particle beams, which emanate from the incidence locations in the second field, onto the third field of the detection regions of the detection system;
a magnetic and/or electrostatic objective lens, through which both the first and the second individual particle beams pass;
a beam switch, which is arranged in the first particle optical beam path between the multi-beam generator and the objective lens and which is arranged in the second particle optical beam path between the objective lens and the detection system;
an aberration correction unit for individually correcting one or more aberrations in the first particle optical beam path; and
a controller,
wherein the aberration correction unit has a sequence of electrode arrays comprising at least one first pair of electrode arrays,
wherein the first pair has a first electrode array and a second electrode array,
wherein the first electrode array and the second electrode array each have a multiplicity of geometry-based correction electrodes each having n-fold rotational symmetry about the optical axis for multipole field generation, which are each controllable individually via exactly one feed line,
wherein the geometry-based correction electrodes in the first electrode array are rotated relative to associated geometry-based correction electrodes in the second electrode array in relation to the optical axis; and
wherein the controller is designed to control the multiplicity of geometry-based correction electrodes of the first electrode array and of the second electrode array of the aberration correction unit individually for an aberration correction.

Example 2: Multi-beam particle microscope according to the preceding example,
wherein an angle of rotation by which the geometry-based correction electrodes of the first pair are rotated with respect to one another is substantially 90°/n.

Example 3: Multi-beam particle microscope according to either of the preceding examples,
wherein the aberration correction unit has a second pair of electrode arrays,
wherein the second pair has a third electrode array and a fourth electrode array,
wherein the third electrode array and the fourth electrode array each have a multiplicity of geometry-based correction electrodes each having m-fold rotational symmetry about the optical axis for multipole field generation, which are each controllable individually via exactly one feed line,
wherein the geometry-based correction electrodes in the third electrode array are rotated relative to associated geometry-based correction electrodes in the fourth electrode array in relation to the optical axis; and
wherein the controller is designed to control the multiplicity of geometry-based correction electrodes of the third electrode array and of the fourth electrode array of the aberration correction unit individually for an aberration correction.

Example 4: Multi-beam particle microscope according to the preceding example,
wherein an angle of rotation by which the geometry-based correction electrodes of the second pair are rotated with respect to one another is substantially 90°/m.

Example 5: Multi-beam particle microscope according to any of the preceding examples,
wherein the aberration correction unit has a third pair of electrode arrays,
wherein the third pair has a fifth electrode array and a sixth electrode array,
wherein the fifth electrode array and the sixth electrode array each have a multiplicity of geometry-based correction electrodes each having k-fold rotational symmetry about the optical axis for multipole field generation, which are each controllable individually via exactly one feed line,
wherein the geometry-based correction electrodes in the fifth electrode array are rotated relative to associated geometry-based correction electrodes in the sixth electrode array in relation to the optical axis; and
wherein the controller is designed to control the multiplicity of geometry-based correction electrodes of the fifth electrode array and of the sixth electrode array of the aberration correction unit individually for an aberration correction.

Example 6: Multi-beam particle microscope according to the preceding example,
wherein an angle of rotation by which the geometry-based correction electrodes of the third pair are rotated with respect to one another is substantially 90°/k.

Example 7: Multi-beam particle microscope according to any of the preceding examples,
wherein different pairs of electrode arrays have different orders of symmetry in the case of their respective geometry-based correction electrodes for generating different multipole fields.

Example 8: Multi-beam particle microscope according to any of the preceding examples,
wherein the geometry-based correction electrodes of a pair of electrode arrays are embodied so as to be round in cross-section and wherein the round correction electrodes in each of the electrode arrays forming the pair are displaced relative to the optical axis orthogonally with respect to the optical axis in different directions, for example by approximately 90°; and
wherein the controller is configured to control the round correction electrodes individually for an aberration correction, for example to control them substantially for correcting a static distortion of the second field of first individual particle beams upon incidence in the object plane.

Example 9: Multi-beam particle microscope according to any of the preceding examples,
wherein the geometry-based correction electrodes of a pair of electrode arrays are embodied so as to be substantially elliptic in cross-section in order to generate a quadrupole field and wherein the substantially elliptic correction electrodes in each of the electrode arrays forming the pair are rotated relative to one another about the optical axis, for example by substantially 45°; and
wherein the controller is configured to control the cross-sectionally elliptic correction electrodes substantially for individually correcting an astigmatism of the first individual particle beams.

Example 10: Multi-beam particle microscope according to any of the preceding examples,
wherein the geometry-based correction electrodes of a pair of electrode arrays are embodied so as to have substantially a rounded triangular shape in cross-section in order to form a hexapole field and wherein the correction electrodes having substantially a rounded triangular shape in cross-section in each of the electrode arrays forming the pair are rotated relative to one another about the optical axis, for example by substantially 30°; and
wherein the controller is configured to individually control the correction electrodes having substantially a triangular shape in cross-section substantially for correcting aberrations having three-fold symmetry.

Example 11: Multi-beam particle microscope according to any of the preceding examples,
wherein the sequence of electrode arrays of the aberration correction unit has a further electrode array comprising a multiplicity of geometry-based correction electrodes which have a round cross-section and which are arranged in a centred fashion in relation to the respective optical axis; and
wherein the controller is designed to control the multiplicity of geometry-based correction electrodes of the further electrode array individually substantially for correcting a focus position of the first individual particle beams, for example for image field curvature correction and/or image field inclination correction.

Example 12: Multi-beam particle microscope according to any of the preceding examples,
wherein the electrode arrays are each integrated into a multi-aperture plate.

Example 13: Multi-beam particle microscope according to the preceding example,
wherein a standard multi-aperture plate having a multiplicity of passive round apertures is arranged between two mutually adjacent multi-aperture plates with, integrated therein, electrode arrays having individually controllable geometry-based correction electrodes.

Example 14: Multi-beam particle microscope according to either of examples 12 and 13,
wherein the aberration correction unit has a standard multi-aperture plate having a multiplicity of passive round apertures, which is arranged, in relation to the direction of the particle optical beam path, upstream of the first multi-aperture plate with individually controllable geometry-based correction electrodes; and/or
wherein the aberration correction unit has a standard multi-aperture plate having a multiplicity of passive round apertures, which is arranged, in relation to the direction of the particle optical beam path, downstream of the last multi-aperture plate with individually controllable geometry-based correction electrodes.

Example 15: Multi-beam particle microscope according to any of examples 1 to 11,
wherein the aberration correction unit provides a carrier plate for a pair of electrode arrays, the geometry-based electrodes of the first electrode array being arranged on the top side of the carrier plate and the geometry-based electrodes of the second electrode array being arranged on the underside of the carrier plate.

Example 16: Multi-beam particle microscope according to any of examples 1 to 11,
wherein the aberration correction unit provides a carrier plate for a pair of electrode arrays, the geometry-based electrodes of the first electrode array being incorporated into the carrier plate on the top side and the geometry-based electrodes of the second electrode array being incorporated into the carrier plate on the underside.

Example 17: Multi-beam particle microscope according to any of the preceding examples,
which furthermore has a multipole amplitude input unit, via which a user can input amplitudes to be generated of fundamental multipoles, and
wherein the controller is designed to generate the control signals for controlling the geometry-based correction electrodes on the basis of the user input.

Example 18: Multi-beam particle microscope according to any of the preceding examples,
wherein the controller is designed to carry out the ascertaining of control signals for controlling the geometry-based correction electrodes for multipole field generation using an inverted amplitude matrix, wherein the non-inverted amplitude matrix describes the relationship between the excitations of the correction electrodes and the amplitudes of the fundamental multipoles generated.

Example 19: Method for adjusting an aberration correction for a multi-beam particle microscope according to any of the preceding claims, the method having the following steps:
a) for all geometry-based correction electrodes of a sequence:
   a1) exciting only one of the geometry-based correction electrodes;
   a2) determining all of the amplitudes of multipoles generated by the individual excitation;
b) establishing an amplitude matrix on the basis of the ascertained amplitudes; and
c) inverting the amplitude matrix.

Example 20: Method according to the preceding example,
wherein the method step a2) comprises: compensating for the effect of the multipole respectively generated, via a global multipole corrector, for example via a twelve-pole corrector, and ascertaining an amplitude respectively used for this purpose in the global multipole corrector.

Example 21: Method according to any of examples 18 to 20, which furthermore has the following step:
d) optimizing the resolution of the multi-beam particle microscope comprising independently varying the amplitudes of each multipole and ascertaining the optimum amplitudes for the resolution.

Example 22: Method according to any of examples 18 to 21,
wherein the method is carried out for all the sequences of the geometry-based correction electrodes.

Example 23: Computer program product having a program code for carrying out the method according to any of examples 18 to 22.

Example 24: Multi-beam particle beam system, having the following features:
a multi-beam generator configured to generate a first field of a multiplicity of charged first individual particle beams;
a particle optical unit with a first particle optical beam path, configured to image the generated individual particle beams onto a sample surface in the object plane such that the individual particle beams are incident on the sample surface at incidence locations, which form a second field;
an aberration correction unit for individually correcting one or more aberrations in the particle optical beam path; and
a controller,
wherein the aberration correction unit has at least one electrode array,
wherein the electrode array has a multiplicity of geometry-based correction electrodes each having n-fold rotational symmetry about the optical axis for multipole field generation, which are each controllable individually via for example exactly one feed line, and
wherein the controller is designed to control the multiplicity of geometry-based correction electrodes of the electrode array of the aberration correction unit individually for an aberration correction.

Example 25: Multi-beam particle beam system according to example 24,
wherein the aberration correction unit has a further electrode array,
wherein the further electrode array has a multiplicity of geometry-based correction electrodes each having m-fold rotational symmetry about the optical axis for multipole field generation, which are each controllable individually via exactly one feed line; and
wherein the controller is designed to control the multiplicity of geometry-based correction electrodes of the further electrode array of the aberration correction unit individually for an aberration correction.

Example 26: Multi-beam particle beam system according to either of examples 24 and 25,
wherein the aberration correction unit has one further electrode array or a plurality of further electrode arrays, the electrodes of which are embodied so as to be geometry-based and/or non-geometry-based.

Example 27: Multi-beam particle beam system according to example 26,
wherein the geometry-based correction electrodes of at least one electrode array are for their part segmented; and
wherein the controller is designed to control the segments of the correction electrodes in turn individually.

### LIST OF REFERENCE SIGNS

1 Multi-beam particle microscope
3 Primary particle beams (individual particle beams)
5 Beam spots, incidence locations
7 Object, sample
9 Secondary particle beams
10 Computer system, controller
15 Sample surface
101 Object plane
102 Objective lens
103 Electromagnetic lens
105 Axis
200 Detector system
205 Projection lens system
209 Detection system, particle multi-detector, detection unit
210 Lens
220 Lens
222 Contrast stop
300 Beam generating apparatus
301 Particle source
303 Collimation lens system
304 Multi-aperture plate, filter plate
305 Multi-aperture arrangement
306 Micro-optics
307 Field lens
308 Field lens
309 Diverging particle beam
323 Beam foci
325 Intermediate image plane
361 Opening
370 Multi-aperture plate
372 Octupole electrode
373 individual electrode of the octupole electrode
375 Electronic circuit
377 Line
379 Serial data connection
381 Vacuum jacket
382 Seal
400 Beam switch, magnet arrangement
500 Scan deflector
600 Displacement stage or positioning device
701 Geometry-based correction electrode
702 Geometry-based correction electrode
703 Opening
704 Opening
705 Geometry-based correction electrode
706 Geometry-based correction electrode
707 Opening
708 Opening
709 Geometry-based correction electrode
710 Geometry-based correction electrode
711 Opening
712 Opening
713 Geometry-based correction electrode
714 Opening
715 Multi-aperture plate
716 Multi-aperture plate
717 Line
718 Line
720 Electrode array
721 Electrode array
722 Electrode array
723 Electrode array
724 Multi-aperture plate
725 Multi-aperture plate
726 Geometry-based correction electrode
727 Opening
728 Geometry-based correction electrode
729 Opening
730 Standard multi-aperture plate
73 Opening
732 Standard multi-aperture plate
733 Opening
734 Carrier plate
735 Insulation
736 Carrier plate
737 Standard multi-aperture plate
738 Opening
740 First pair of electrode arrays
741 Second pair of electrode arrays
742 Third pair of electrode arrays
744 Geometry-based correction electrode
745 Opening
746 Geometry-based correction electrode
747 Opening
748 Geometry-based correction electrode
749 Opening
750 Aberration correction unit
751 Multi-aperture plate
h Thickness of a multi-aperture plate with electrode array
Z Optical axis
S0 Providing a multi-beam particle microscope having an aberration correction unit according to the disclosure
S1 Exciting a first geometry-based correction electrode of a sequence
S2 Determining the amplitude of the first multipole thus generated
S3 Determining the amplitude of the second multipole thus generated
S4 Determining the amplitude of the third multipole thus generated
S5 Exciting the second geometry-based correction electrode of the sequence
S6 Determining the amplitude of the first multipole thus generated
S7 Determining the amplitude of the second multipole thus generated
S8 Determining the amplitude of the third multipole thus generated
S9 Establishing an amplitude matrix on the basis of the ascertained amplitudes
S10 Inverting the amplitude matrix

1. A multi-beam particle microscope, comprising:
a multi-beam generator configured to generate a first field of a multiplicity of charged first individual particle beams;
a first particle optical unit with a first particle optical beam path, the first particle optical unit configured to image the charged first individual particle beams onto a sample surface in an object plane so that the first charged individual particle beams are incident on the sample surface at incidence locations defining a second field;
a detection system comprising a multiplicity of detection regions defining a third field;
a second particle optical unit with a second particle optical beam path, the second particle optical unit configured to image second charged individual particle beams, which emanate from the incidence locations in the second field, onto the third field of the detection regions of the detection system;
a magnetic and/or electrostatic objective lens, through which both the first and the second charged individual particle beams pass;
a beam switch in the first particle optical beam path between the multi-beam generator and the objective lens, the beam switch in the second particle optical beam path between the objective lens and the detection system;
an aberration correction unit configured to individually correct an aberration in the first particle optical beam path; and
a controller,
wherein:
the aberration correction unit comprises a first pair of electrode arrays;
the first pair of electrode arrays comprises a first electrode array and a second electrode array;
each of the first and second electrode arrays comprises a multiplicity of geometry-based correction electrodes each having n-fold rotational symmetry about an optical axis to generate a multipole field;
each of the geometry-based correction electrodes is individually controllable via exactly one feed line;
relative to the optical axis, the geometry-based correction electrodes in the first electrode array are rotated relative to associated geometry-based correction electrodes in the second electrode array; and
the controller is configured to individually control the multiplicity of geometry-based correction electrodes of the first and second electrode arrays to correct the aberration.

2. The multi-beam particle microscope of claim 1, wherein the geometry-based correction electrodes of the first pair of electrode arrays are rotated with respect to one another at angle of substantially 90°/n.

3. The multi-beam particle microscope of claim 1, wherein:
the aberration correction unit comprises a second pair of electrode arrays;
the second pair of electrode arrays comprises a third electrode array and a fourth electrode array;
each of the third fourth electrode arrays comprises a multiplicity of geometry-based correction electrodes each having m-fold rotational symmetry about the optical axis to generate a multipole field;
each of the geometry-based correction electrodes of the third and fourth electrode arrays is individually controllable via exactly one feed line;
relative to the optical axis, the geometry-based correction electrodes in the third electrode array are rotated relative to associated geometry-based correction electrodes in the fourth electrode array; and
the controller is configure to individually control the multiplicity of geometry-based correction electrodes of the third and of fourth electrode arrays of the aberration correction unit to correct the aberration.

4. The multi-beam particle microscope of claim 3, wherein the geometry-based correction electrodes of the second pair of electrode arrays are rotated with respect to one another at an angle that is substantially 90°/m.

5. The multi-beam particle microscope of claim 3, wherein:
the aberration correction unit comprises a third pair of electrode arrays;
the third pair of electrode arrays comprises a fifth electrode array and a sixth electrode array;
each of the fifth and sixth electrode arrays comprises a multiplicity of geometry-based correction electrodes each having k-fold rotational symmetry about the optical axis to generate the multipole field;
each of the geometry-based correction electrodes of the fifth and sixth electrode arrays is individually controllable via exactly one feed line;
relative to the optical axis, the geometry-based correction electrodes in the fifth electrode array are rotated relative to associated geometry-based correction electrodes in the sixth electrode array in relation; and
the controller is configured to control the multiplicity of geometry-based correction electrodes of the fifth electrode array and of the sixth electrode array of the aberration correction unit individually to correct the aberration.

6. The multi-beam particle microscope of claim 5, wherein the geometry-based correction electrodes of the third pair of electrode arrays are rotated with respect to one another at an angle that is substantially 90°/k.

7. The multi-beam particle microscope of claim 1, wherein different pairs of electrode arrays have different orders of symmetry in the case of their respective geometry-based correction electrodes to generate different multipole fields.

8. The multi-beam particle microscope of claim 1, wherein:
the geometry-based correction electrodes of the first pair of electrode arrays are round in cross-section;
relative to the optical axis, the round correction electrodes in each of the electrode arrays defining the pair of electrode arrays are displaced orthogonally in different directions with respect to the optical axis; and
the controller is configured to individually control the round correction electrodes to correct the aberration.

9. The multi-beam particle microscope of claim 1, wherein:
the geometry-based correction electrodes of the first pair of electrode arrays are substantially elliptic in cross-section to generate a quadrupole field;
the substantially elliptic correction electrodes in each of the electrode arrays defining the first electrode pair are rotated relative to one another about the optical axis; and
the controller is configured to control the cross-sectionally elliptic correction electrodes substantially to individually correct an astigmatism of the first individual particle beams.

10. The multi-beam particle microscope of claim 1, wherein:
the geometry-based correction electrodes of the first pair of electrode arrays are have a substantially rounded triangular shape in cross-section to form a hexapole field; and
the correction electrodes having the substantially rounded triangular shape in cross-section in each of the electrode arrays forming the pair are rotated relative to one another about the optical axis; and
the controller is configured to individually control the correction electrodes having the substantially triangular shape in cross-section substantially to correct aberrations having three-fold symmetry.

11. The multi-beam particle microscope of claim 1, wherein:
wherein the sequence of electrode arrays of the aberration correction unit has a further electrode array comprising a multiplicity of geometry-based correction electrodes which have a round cross-section and which are arranged in a centred fashion in relation to the respective optical axis; and
wherein the controller is designed to control the multiplicity of geometry-based correction electrodes of the further electrode array individually substantially for correcting a focus position of the first individual particle beams, in particular for image field curvature correction and/or image field inclination correction.

12. The multi-beam particle microscope of claim 1, wherein the each of the first and second electrode arrays is integrated into a multi-aperture plate.

13. The multi-beam particle microscope of claim 12, wherein a multi-aperture plate comprising a multiplicity of passive round apertures is between two mutually adjacent multi-aperture plates with, integrated therein, electrode arrays comprising individually controllable geometry-based correction electrodes.

14. The multi-beam particle microscope of claim 12, wherein:
the aberration correction unit comprises a multi-aperture plate comprising a multiplicity of passive round apertures, which is arranged, in relation to a direction of the particle optical beam path, upstream of a multi-aperture plate comprising individually controllable geometry-based correction electrodes; and/or
the aberration correction unit comprises a multi-aperture plate comprising a multiplicity of passive round apertures, which is arranged, in relation to the direction of the particle optical beam path, downstream of the last multi-aperture plate with individually controllable geometry-based correction electrodes.

15. The multi-beam particle microscope of claim 1, wherein:
the aberration correction unit comprises a carrier plate for a pair of electrode arrays;
the geometry-based correction electrodes of the first electrode array are on a first side of the carrier plate;
the geometry-based correction electrodes of the second electrode array are on a second side of the carrier plate;
the second side of the carrier plate is opposite the first side of the carrier plate.

16. The multi-beam particle microscope of claim 1, wherein:
the aberration correction unit comprises a carrier plate for a pair of electrode arrays;
the geometry-based correction electrodes of the first electrode array are incorporated into the carrier plate on a first top side;
the geometry-based correction electrodes of the second electrode array are incorporated into the carrier plate on a second side; and
the second side is opposite the first side.

17. The multi-beam particle microscope of claim 1, further comprising a multipole amplitude input unit configured to input amplitudes of fundamental multipoles to be generated, wherein the controller is configured to generate the control signals to control the geometry-based correction electrodes based on the amplitudes of the fundamental multipoles.

18. The multi-beam particle microscope of claim 1, wherein the controller is configured to determine control signals to control the geometry-based correction electrodes via an inverted amplitude matrix, and a non-inverted amplitude matrix describes a relationship between excitations of the correction electrodes and amplitudes of fundamental multipoles generated.

19. The multi-beam particle microscope of claim 1, wherein the controller is configured to individually control the geometry-based correction electrodes to correct a previously known field-dependent aberration.

20. A method of generating fundamental multipoles for an aberration correction in a multi-beam particle microscope, the method comprising:
a) providing a multi-beam particle microscope according to claim 1;
b) for all geometry-based correction electrodes of a sequence:
b1) exciting only one of the geometry-based correction electrodes;
b2) determining all of the amplitudes of multipoles generated by the individual excitation;
c) establishing an amplitude matrix based on the determined amplitudes, wherein the amplitude matrix describes a relationship between the excitations of the geometry-based correction electrodes and the amplitudes of the fundamental multipoles generated by these excitations;
d) inverting the amplitude matrix; and
e) exciting the geometry-based correction electrodes based on the entries of the inverted amplitude matrix.

21.-27. (canceled)
